(19) United States
(12) Patent Application Publication
(10) Pub. No.: US 2026/0141834 A1
(43) Pub. Date: May 21, 2026

(54) DISPLAY PANEL AND DISPLAY APPARATUS

(71) Applicant: Shanghai Tianma Microelectronics Co., Ltd., Shanghai (CN)

(72) Inventors: Nana XIONG, Shanghai (CN); Mengying JIANG, Shanghai (CN); Shengjuan LIU, Shanghai (CN); Ning KANG, Shanghai (CN); Chong QIAN, Shanghai (CN)

(21) Appl. No.: 19/433,047

(22) Filed: Dec. 25, 2025

(30) Foreign Application Priority Data
Jun. 11, 2025 (CN) 202510779313.X

(51) Int. Cl. G09G 3/00; G09G 3/20; H10K 59/38

(52) U.S. Cl. CPC G09G 3/006; G09G 3/2007; H10K 59/38; G09G 2320/0233; G09G 2330/12; G09G 2360/145

(57) ABSTRACT

Provided are a display panel and a display apparatus. The display panel includes a substrate, an array layer and a light-emitting element that are provided at a same side of the substrate, and a photosensitive unit. The light-emitting element is provided at a side of the array layer away from the substrate. The light-emitting element includes a first and a second light-emitting elements. The first light-emitting element is provided in a display area of the display panel, and the second light-emitting element is provided in a non-display area of the display panel. The photosensitive unit includes a photosensitive element located in the non-display area, and the photosensitive element is configured to sense light emitted by the second light-emitting element. The luminance attenuation of the second light-emitting element can be monitored by the photosensitive unit, and the luminance attenuation of the light-emitting element in the display area can be obtained.

### CROSS-REFERENCE TO RELATED APPLICATION

The present application claims priority to Chinese Patent Application No. 202510779313.X, filed on Jun. 11, 2025, the content of which is incorporated herein by reference in its entirety.

### TECHNICAL FIELD

The present disclosure relates to the technical field of displaying, and, in particular, to a display panel and a display apparatus.

### BACKGROUND

With the development of science and technology, more and more display products, such as mobile phones, tablets, laptops and smart wearable devices, have been widely used in people's daily life and work, thereby resulting in great convenience, and becoming indispensable tools for people at present.

A common display product includes multiple light-emitting elements, and the lifespan of the light-emitting elements directly affects the lifespan of the display product. Nowadays, therefore, how to effectively monitor the lifespan of the light-emitting elements to achieve lifespan monitoring of the display product has become one of the urgent technical problems to be solved.

### SUMMARY

In order to solve the above technical problems, embodiments of the present disclosure provides a display panel and a display apparatus, which are intend to realize the lifespan monitoring function of the display product.

In a first aspect, an embodiment of the present disclosure provides a display panel, including: a substrate, an array layer and a light-emitting element provided at a same side of the substrate, and a photosensitive unit. The light-emitting element is provided at a side of the array layer away from the substrate. The light-emitting element includes a first light-emitting element and a second light-emitting element. The first light-emitting element is provided in a display area of the display panel, and the second light-emitting element is provided in a non-display area of the display panel. The photosensitive unit includes a photosensitive element provided in the non-display area, and the photosensitive element is configured to sense light emitted by the second light-emitting element.

In a second aspect, an embodiment of the present disclosure provides a display apparatus, including the display panel according to the first aspect of the present disclosure.

Compared with the prior art, the technical solutions according to the embodiments of the present disclosure have the following advantages.

### BRIEF DESCRIPTION OF DRAWINGS

The drawings herein, which are incorporated in and constitute a part of this specification, illustrate embodiments in accordance with the present disclosure, together with the specification, serve to explain the principles of the present disclosure.

To clearly illustrate the technical solutions of the embodiments of the present disclosure or the prior art, the drawings required in the embodiments or the prior art are briefly introduced below. It is appreciated that other drawings may be obtained by those skilled in the art according to these drawings without any creative effort.

FIG. 1 is a planar structural diagram of a display panel according to some embodiments of the present disclosure;

FIG. 2 is a cross-sectional view of the display panel taken along AA in FIG. 1;

FIG. 3 is a schematic structural diagram of a photosensitive unit according to some embodiments of the present disclosure;

FIG. 4 is a schematic diagram showing a correspondence between part of second light-emitting elements and display grayscale in a non-display area;

FIG. 5 is a schematic diagram showing a further correspondence between part of second light-emitting elements and display grayscale in a non-display area;

FIG. 6 is a schematic diagram showing a further correspondence between part of second light-emitting elements and display grayscale in a non-display area;

FIG. 7 is a planar structural diagram of a further display panel according to some embodiments of the present disclosure;

FIG. 8 is a planar structural diagram of a further display panel according to some embodiments of the present disclosure;

FIG. 9 is a planar structural diagram of a further display panel according to some embodiments of the present disclosure;

FIG. 10 is a planar structural diagram of a further display panel according to some embodiments of the present disclosure;

FIG. 11 is a schematic structural diagram of a pixel driving circuit according to some embodiments of the present disclosure;

FIG. 12 is schematic structural diagram of a further pixel driving circuit according to some embodiments of the present disclosure;

FIG. 13 is a timing diagram of the pixel driving circuit in FIG. 11;

FIG. 14 is a schematic diagram showing a connection between a pixel driving circuit and a data line of a display panel according to some embodiments of the present disclosure;

FIG. 15 is a schematic circuit diagram of a photosensitive driving circuit according to some embodiments of the present disclosure;

FIG. 16 is a sequence diagram of a photosensitive driving circuit according to some embodiments of the present disclosure;

FIG. 17 is a schematic diagram showing a connection between a photosensitive driving circuit and a photosensitive chip;

FIG. 18 is a schematic diagram showing a connection between a photosensitive driving circuit and a shift register circuit; and

FIG. 19 is a schematic structural diagram of a display apparatus according to some embodiments of the present disclosure.

### DESCRIPTION OF EMBODIMENTS

To clearly understand the above-mentioned purposes, features and advantages of the present disclosure, the technical solutions of the present disclosure will be further described below. It should be noted that the embodiments of the present disclosure and the features in the embodiments may be combined with each other without conflict.

In the following description, many specific details are set forth to fully understand the present disclosure, but the present disclosure may be implemented in other manners different from those described herein. It is apparent that the embodiments in the specification are just some, rather than all, of the embodiments of the present disclosure.

For organic light-emitting diode (OLED) display products, there is a problem that the lifespan of the luminescent materials in the light-emitting elements will decay after a long period of lighting, thereby resulting in overall lifespan decay of the OLED display products. The decay speeds corresponding to light-emitting elements of different colors may be inconsistent, thereby showing a certain deviation in the color temperature trajectory of the OLED display products in terms of optical visual effects. Therefore, how to monitor the lifespan of OLED display products in real time to selectively perform luminance compensation on OLED display products and improve the visual effects of OLED display products has become one of the urgent technical problems to be solved at present.

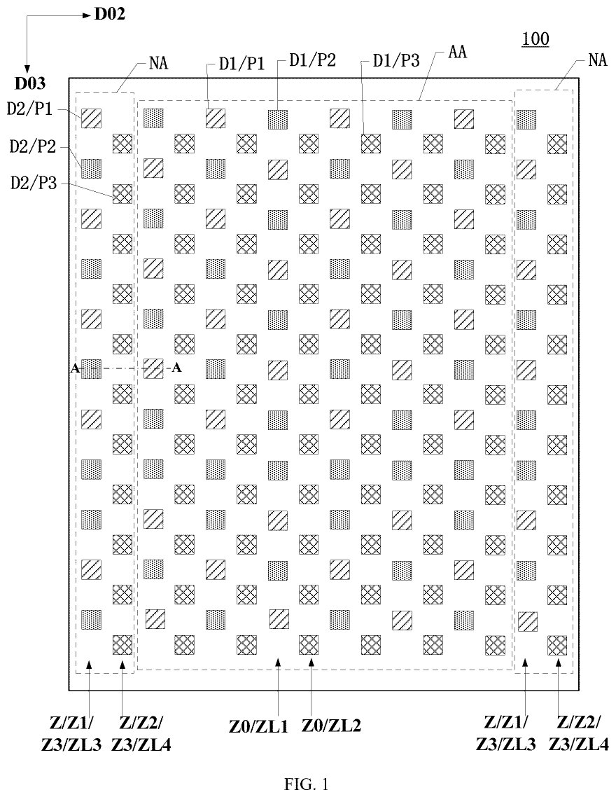

In view of the above, an embodiment of the present disclosure provides a display panel. FIG. 1 is a planar structural diagram of a display panel according to some embodiments of the present disclosure. FIG. 2 is a cross-sectional view of the display panel taken along AA in FIG. 1. It should be noted that FIG. 1 merely illustrates a relative position relationship between a first light-emitting element D1 and a second light-emitting element D2 of the display panel, and does not limit the quantity and arrangement of the first light-emitting element D1 and the second light-emitting element D2 actually included in the display panel. The first light-emitting element D1 and the second light-emitting element D2 are just illustrated in a rectangular structure, but should not be construed as limiting the present disclosure. In some other embodiments of the present disclosure, the first light-emitting element D1 and the second light-emitting element D2 may also be embodied in other top-view shapes, such as circles and diamonds.

Referring to FIG. 1 and FIG. 2, a display panel 100 according to an embodiment of the present disclosure includes: a substrate 00, and an array layer 01 and a light-emitting element D provided at a same side of the substrate 00. The light-emitting element D is provided at a side of the array layer 01 away from the substrate 00. The light-emitting element D includes a first light-emitting element D1 and a second light-emitting element D2. The first light-emitting element D1 is provided in a display area AA of the display panel, and the second light-emitting element D2 is provided in a non-display area NA of the display panel. The display panel 100 further includes a photosensitive unit 90. The photosensitive unit 90 includes a photosensitive element 91 located in the non-display area NA. The photosensitive element 91 is configured to sense the light emitted by the second light-emitting element D2 and convert the light signal into an electrical signal.

In an embodiment, as shown in FIG. 1, the non-display area NA surrounds the display area AA, which is illustrated as an example, should not be construed as limiting the present disclosure. In some other embodiments of the present disclosure, the non-display area NA may also be arranged to partially surround the display area AA. The display area AA may be interpreted as an area for displaying images, while the non-display area NA may be interpreted as an area for displaying no image in the display panel, such as a frame area of the display panel. In some embodiments of the present disclosure, the display panel according to the embodiments of the present disclosure is an OLED display panel, and the light-emitting element D is a light-emitting element including an organic luminescent material.

The display panel according to some embodiments of the present disclosure includes the first light-emitting element D1 located in the display area AA and the second light-emitting element D2 located in the non-display area NA, and a photosensitive unit 90 integrated in the non-display area NA. The photosensitive element 91 in the photosensitive unit 90 can sense the light emitted by the second light-emitting element D2 and convert the light signal into an electrical signal, which is equivalent to realizing the light emission monitoring of the second light-emitting element D2. The efficiency of the luminescent material of the light-emitting element D may gradually decrease over time, thereby resulting in a decrease in light intensity under the same driving current, and the electrical signal intensity sensed by the photosensitive unit 90 may also decrease accordingly. The aging degree of the second light-emitting element D2 can be evaluated by monitoring the changes in the signal intensity of the photosensitive unit 90, that is, the lifespan monitoring of the second light-emitting element D2 is realized. Due to the fact that the second light-emitting element D2 and the first light-emitting element D1 are provided in the same display panel, and have similar lifespan decay characteristics, the lifespan status of the first light-emitting element D1 in the display area AA can be inferred by monitoring the changes in the light signal of the second light-emitting element D2 in the non-display area NA. According to the lifespan status of the first light-emitting element D1, luminance compensation can be selectively performed on the first light-emitting element D1 in the display area AA(for example, dynamically adjusting the driving voltage or current), thereby realizing more refined luminance control and color management, effectively improving the visual effect of the display panel, weakening or avoiding the color cast problem caused by luminance attenuation, and facilitating extending the overall service lifespan of the display panel.

In addition, in the present disclosure, the second light-emitting element D2 and the photosensitive unit 90 are introduced in the non-display area NA of the display panel, such that the lifespan of the light-emitting element can be monitored in real time during the operation of the display panel without disassembly or destructive testing, thereby reducing the difficulty of monitoring. Compared with relying on laboratory test data, this integrated monitoring solution can better reflect the changes in the lifespan of the light-emitting element in actual usage environments and obtain more accurate monitoring data. Meanwhile, in some embodiments of the present disclosure, the second light-emitting element D2 and the corresponding photosensitive unit 90 are provided in the non-display area NA of the display panel, which is beneficial to avoiding affecting the first light-emitting element D1 and related circuit structures in the display area AA.

Referring to FIG. 2, in an embodiment of the present disclosure, the photosensitive element 91 overlaps with the second light-emitting element D2 along a first direction D01. The first direction D01 is perpendicular to a plane of the substrate 00.

In an embodiment, the relative position relationship between the photosensitive element 91 and the second light-emitting element D2 is further refined. The photosensitive element 91 can receive the light emitted by the second light-emitting element D2 more directly and effectively by arranging the photosensitive element 91 to overlap with the second light-emitting element D2 in the vertical direction, which facilitates increasing the intensity of the light signal received by the photosensitive element 91, thereby improving the sensitivity and signal-to-noise ratio of monitoring. Moreover, the vertically overlapping design can reduce the lateral stray light interference from the surrounding environment or other pixels, such that the light signal received by the photosensitive element 91 comes more purely from the second light-emitting element D2. In addition, the photosensitive element 91 is arrange to vertically overlap the second light-emitting element D2, which facilitates realizing a more compact non-display area NA design and reducing the width of the frame.

In some other embodiments of the present disclosure, the photosensitive element 91 may be provided on the peripheral side of the second light-emitting element D2. In the plan view, the photosensitive element 91 does not overlap with the second light-emitting element D2, and the photosensitive element 91 can sense the side light emitted by the second light-emitting element D2.

Referring to FIG. 2, in an embodiment of the present disclosure, the display panel includes a color filter layer 04 provided at the side of the light-emitting element away from the substrate 00. The color filter layer 04 includes a light-transmitting portion 41 and a light-shielding portion 42. Along the first direction D01, the light-transmitting portion 41 overlaps with the first light-emitting element D1 and does not overlap with the second light-emitting element D2, and the light-shielding portion 42 overlaps with the second light-emitting element D2. The first direction D01 is perpendicular to the plane of the substrate 00.

In an embodiment, the color filter layer 04 is introduced in the light-emitting direction of the first light-emitting element D1. The light-transmitting portion 41 in the color filter layer 04 overlaps with the first light-emitting element D1, and the light-transmitting portion 41 can be used to filter the spectrum of the light emitted by the first light-emitting element D1, so that the color purity is high. The light-transmitting portion 41 in the color filter layer 04 can be regarded as a filter layer, and its color is the same as the light-emitting color of the corresponding first light-emitting element D1. In the display area AA, the light-transmitting portion 41 covers the first light-emitting element D1 in the display area AA, and the light-shielding portion 42 covers the area between adjacent light-emitting elements. The light-shielding portion 42 can absorb ambient light to block the reflection of external light, thereby improving the contrast of the display panel. In the non-display area NA, the light-shielding portion 42 overlaps with the second light-emitting element D2, for example, the light-shielding portion 42 can cover the entire non-display area NA, so that the light from the second light-emitting element D2 can be blocked from being incident on the light-emitting surface of the display panel, and the external ambient light can also be blocked from being incident on the second light-emitting element D2 and the photosensitive unit 90, thereby helping to reduce the influence of the ambient light on the light signal sensed by the photosensitive unit 90, and improving the monitoring stability of the photosensitive unit 90 under different lighting conditions. In addition, the light-shielding portion 42 in the color filter layer 04 is used to shield the external light from the second light-emitting element D2 and the photosensitive unit 90, which can simplify the panel structure and reduce additional manufacturing costs and process complexity.

Referring to FIG. 2, in an embodiment of the present disclosure, the light-emitting element includes a first electrode 21, a luminescent material layer 23 and a second electrode 22. Along the first direction D01, the luminescent material layer 23 is provided between the first electrode 21 and the second electrode 22, and the first electrode 21 is provided at a side of the luminescent material layer 23 facing the array layer 01. The first direction D01 is perpendicular to the plane of the substrate 00. The first electrode 21 of the second light-emitting element D2 is a transparent conductive layer, and the photosensitive element 91 is provided at a side of the second light-emitting element D2 facing the substrate 00.

In an embodiment, the first electrode 21 of the light-emitting element D is, for example, an anode, and the second electrode 22 is, for example, a cathode. When the power supply supplies an appropriate voltage, the holes generated by the first electrode 21 and the electrons generated by the second electrode 22 recombine in the luminescent material layer 23 to generate light. In some embodiments of the present disclosure, the display panel includes the substrate 00, the array layer 01, and a display layer 02. A pixel driving circuit is provided in the array layer 01 for providing a driving voltage to the light-emitting element D to drive the light-emitting element D to emit light. The display layer 02 includes a pixel definition layer 19, which defines a plurality of pixel openings. The luminescent material layer 23 is at least provided in the pixel openings. Along the direction perpendicular to the substrate 00, the first electrode 21 and the second electrode 22 are provided at two sides of the luminescent material layer 23, respectively, and the first electrode 21 is provide at a side of the second electrode 22 facing the substrate 00. The pixel definition layer can be a light-shielding material layer. In some embodiments of the present disclosure, an encapsulation layer 03 is further provided at a side of the second electrode 22 away from the first electrode 21. In some embodiments of the present disclosure, the encapsulation layer 03 includes a first inorganic layer 31, an organic layer 32, and a second inorganic layer 33 arranged in a stacked manner. The color filter layer 04 is provided at a side of the encapsulation layer 03 away from the substrate 00.

Regarding the second light-emitting element D2 provided in the non-display area NA, since the light emitted by it is provided to the photosensitive element 91, considering that the photosensitive element 91 is provided at a side of the second light-emitting element D2 facing the substrate 00, when the first electrode 21 of the second light-emitting element D2 is set as a transparent electrode, the light emitted downward by the second light-emitting element D2 can be incident on the photosensitive element 91 provided below it through the transparent first electrode 21. The photosensitive element 91 can directly receive the light emitted by the second light-emitting element D2, and the signal strength is relatively strong, which is conducive to improving the monitoring sensitivity. Moreover, by placing the photosensitive element 91 below the second light-emitting element D2, the space in the non-display area (NA region) can be utilized more efficiently, avoiding additional occupation of planar space. In practical applications, a current is applied to the second light-emitting element D2 to excite the luminescent material layer 23 to emit light. The photosensitive element 91 receives the light emitted by the second light-emitting element D2 and converts it into an electrical signal. The efficiency of the luminescent material may gradually decrease over time, resulting in a decrease in light intensity under the same driving current, and the electrical signal intensity sensed by the photosensitive element 91 may also decrease accordingly. The aging degree of the second light-emitting element D2 can be evaluated by monitoring the changes in the signal intensity of the photosensitive element 91, based on which the lifespan status of the first light-emitting element D1 in the entire display panel can be inferred.

It should be noted that when the first electrode 21 of the second light-emitting element D2 is formed using a transparent conductive layer, such as indium tin oxide (ITO) or other transparent materials, the first electrode 21 of the first light-emitting element D1 in the display area can be formed using a non-transparent conductive layer, such as a stacked structure of three metal layers ITO/Ag/ITO, to reduce contact resistance and improve conductivity.

Referring to FIG. 2, in an embodiment of the present disclosure, the photosensitive unit 90 introduced in the non-display area NA is provided in the array layer 01. In the present disclosure, the photosensitive unit 90 is directly integrated in the array layer 01, which can completely utilize the existing thin film transistor process, avoid the need to provide the photosensitive unit 90 under the substrate 00 or in an additional area, make the overall structure more compact, and facilitate reducing additional manufacturing steps and costs. The electrical signal generated by the photosensitive unit 90 can be directly read and processed through the lines of the array layer 01, facilitating the integration of the driving circuit. In addition, when the photosensitive unit 90 is integrated in the array layer 01, the distance between the photosensitive unit 90 and the second light-emitting element D2 can be reduced, thereby reducing the distance for the light emitted by the second light-emitting element D2 to be transmitted to the photosensitive unit 90, reducing the attenuation of the light signal, and enabling the photosensitive unit 90 to receive a stronger light signal, which is conducive to improving the monitoring sensitivity and signal-to-noise ratio.

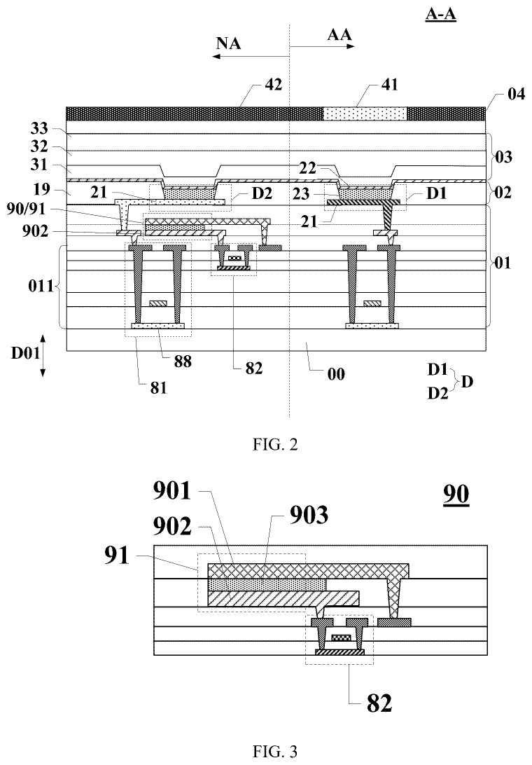

Referring to FIG. 2 and FIG. 3, FIG. 3 is a schematic structural diagram of a photosensitive unit 90 according to some embodiments of the present disclosure. In order to clearly illustrate the structure of the photosensitive unit 90, FIG. 3 only depicts the relevant film layers of the photosensitive unit 90 as an example. In an embodiment of the present disclosure, along the first direction D01, the photosensitive element 91 overlaps with the second light-emitting element D2. The photosensitive element 91 includes a first electrode 901 and a second electrode 902 arranged opposite to each other along the first direction D01, and a photosensitive layer 903 provided between the first electrode 901 and the second electrode 902. The second electrode 902 is provided between the photosensitive layer 903 and the substrate 00, and the second electrode 902 is a light-shielding conductive layer. Referring to FIG. 2, the second light-emitting element D2 is electrically connected to at least one first transistor 81 of the array layer 01. Along the first direction D01, the first transistor 81 is provided at a side of the second electrode 902 facing the substrate 00, and the second electrode 902 overlaps with the first transistor 81.

In an embodiment, the specific structure of the photosensitive unit 90 is described. The photosensitive element 91 in the photosensitive unit 90 overlaps with the second light-emitting element D2 in the first direction D01, which means that the light emitted by the second light-emitting element D2 can be directly incident on the photosensitive element 91, thereby improving the efficiency of receiving the light signal, which is conducive to more accurately monitoring the changes in the luminance of the second light-emitting element D2. The first electrode 901, the second electrode 902 and the photosensitive layer 903 therebetween constitute the basic structure of the photosensitive element 91. In some embodiments of the present disclosure, the photosensitive layer 903 includes one or more PN junctions (or similar heterojunctions). For example, the PN junction may be a PN diode, a PIN diode or other structure. The first electrode 901 and the second electrode 902 are in electrical contact with the P region and the N region, respectively. When light is incident on the depletion region or its vicinity of the PN junction, the photons are absorbed to generate electron-hole pairs. The built-in electric field inside the PN junction can quickly separate these photo-generated electrons and holes, the electrons are swept towards the N region and the holes are swept towards the P region. The function of the first electrode 901 and the second electrode 902 is to receive the photo-generated carriers that are separated and drift to their respective regions. The collected photo-generated electrons and holes flow between the first electrode 901 and the second electrode 902 through an external circuit to form a photo-generated current. The greater the light intensity, the more electron-hole pairs are generated, and the greater the photo-generated current. By monitoring the changes in the photo-generated current, the changes in the lifespan of the second light-emitting element D2 can be monitored.

In an embodiment, the second electrode 902 is configured as a light-shielding conductive layer provided between the photosensitive layer and the substrate 00, the first transistor 81 connected to the second light-emitting element D2 is provided at a side of the light-shielding conductive layer facing the substrate 00, and the first transistor 81 is arranged to overlap with the second electrode 902. In this way, the second electrode 902 can play a role in light-shielding, reducing or avoiding the influence of the light emitted by the second light-emitting element D2 on the electrical performance of the first transistor 81. Meanwhile, the structure of stacking the second electrode 902 and the first transistor 81 in the vertical direction helps to save space in the non-display area NA, which is conducive to realizing the narrow frame design of the display panel. In addition, the first transistor 81 connected to the second light-emitting element D2 is provided in the array layer 01. That is, the transistor in the array layer 01 can be used to drive the second light-emitting element D2, and the second light-emitting element D2 can be driven by using the existing array driving technology, which is conducive to simplifying the overall design of the display panel.

Referring to FIG. 2 and FIG. 3, in an embodiment of the present disclosure, along the first direction D01, the second electrode 902 covers at least part of an active layer 88 of the first transistor 81. The second electrode 902 in the photosensitive unit 90 serves as a light-shielding conductive layer, which is arranged above the active layer 88 of the first transistor 81 and covers at least part of the active layer 88 of the first transistor 81. For example, the second electrode 902 can cover the channel region of the first transistor 81, thereby effectively blocking light from above (for example, the second light-emitting element D2 or ambient light) from directly being incident on the channel region of the transistor. Considering that the active layer 88 of the transistor, especially the channel region, is very sensitive to light, it generates photo-generated carriers when exposed to light, resulting in an increase in the leakage current of the transistor and even causing malfunction. By shielding the active layer 88 with the second electrode 902, such light interference can be significantly reduced, and the electrical performance stability and reliability of the transistor can be improved, which is crucial to ensure the stability of the current driving the second light-emitting element D2, thereby ensuring the stability of the luminous luminance of the second light-emitting element D2 and ultimately improving the accuracy of the lifespan monitoring.

Referring to FIG. 2 and FIG. 3, in an embodiment of the present disclosure, the photosensitive unit 90 further includes at least one second transistor 82 electrically connected to the photosensitive element 91. The array layer 01 includes a transistor layer 011, and the transistor layer 011 includes a plurality of transistors. The second transistor 82 is provided in the transistor layer 011. Along the first direction D01, the photosensitive element 91 is provided between the transistor layer 011 and the second light-emitting element D2, and the first direction D01 is perpendicular to the plane of the substrate 00. In some embodiments of the present disclosure, the transistor layer 011 is provided with P-type transistors and N-type transistors, for example, the first transistor 81 is a P-type transistor, and the second transistor 82 is an N-type transistor, which should not be construed as limiting the present disclosure.

In the present disclosure, by introducing the second transistor 82 to process the signal of the photosensitive element 91, more flexible and optimized control of the photosensitive signal can be achieved. The second transistor 82 electrically connected to the photosensitive element 91 is provided in the transistor layer 011 in the array layer 01, which means that the transistors for driving the display pixels and processing the photosensitive signals are all provided in the transistor layer 011, without the requirement of a film layer structure separately provided for the second transistor 82 corresponding to the photosensitive element 91. Accordingly, most of the steps in the manufacturing process for the thin film transistor of the display panel can be shared, which is conducive to simplifying the manufacturing process and reducing costs.

In addition, in the present disclosure, the photosensitive unit 90 is provided between the transistor layer 011 and the second light-emitting element D2, that is, the photosensitive unit 90 can be integrated in the film layer between the transistor layer 011 and the second light-emitting element D2 of the display panel, which is conducive to rationally utilizing the space of the array layer 01 of the display panel, and reducing the distance between the photosensitive unit 90 and the second light-emitting element D2, so as to reduce the distance for the light emitted by the second light-emitting element D2 to be transmitted to the photosensitive unit 90, reduce the attenuation of the light signal, and enable the photosensitive unit 90 to receive a stronger light signal, thereby improving the monitoring sensitivity and signal-to-noise ratio.

Referring to FIG. 1 and FIG. 2, in an embodiment of the present disclosure, the first light-emitting element D1 and the second light-emitting element D2 include a first color light-emitting element P1, a second color light-emitting element P2 and a third color light-emitting element P3, and the light-emitting layers of the light-emitting elements of the same light-emitting color provided in the display area AA and the non-display area NA are arranged in the same layer. That is, in the display area AA and the non-display area NA, the light-emitting elements of the same light-emitting color are made of the same material and the same process, which can ensure that these light-emitting elements in the display area AA and the non-display area NA have a high degree of consistency in material composition, crystal structure, luminous efficiency, spectral characteristics and initial luminance. Such consistency is critical to the accuracy of the lifespan monitoring. Considering that in the present disclosure, the lifespan of the first light-emitting element D1 in the display area AA is inferred by monitoring the luminance attenuation of the second light-emitting element D2 in the non-display area NA, if there are significant differences in the initial characteristics and decay behavior of the two, the reliability of the monitoring results is reduced. Therefore, in the present disclosure, the light-emitting elements of the same light-emitting color in the display area AA and the non-display area NA are manufactured using the same manufacturing process, which can minimize the difference and improve the accuracy of lifespan prediction.

In addition, the method of sharing process steps for the light-emitting elements of the same light-emitting color in the display area AA and the non-display area NA is conducive to significantly reducing the complexity of the manufacturing process, thereby reducing independent process steps, reducing the links for introducing defects, and improving the yield of the entire panel.

In some embodiments of the present disclosure, the first color light-emitting element P1, the second color light-emitting element P2 and the third color light-emitting element P3 are, for example, red light-emitting element, blue light-emitting element and green light-emitting element, respectively. In the drawings of the present disclosure, different graphic fillings are used to illustrate light-emitting elements of different colors, which should not be construed as limiting the present disclosure. In the display area AA and the non-display area NA, the red light-emitting elements are made in the same using the same process, the blue light-emitting elements are made in the same layer using the same process, and the green light-emitting elements are made in the same layer using the same process. In this way, by monitoring the luminance attenuation of the red light-emitting elements in the non-display area NA, the luminance attenuation of the red light-emitting elements in the display area AA can be inferred. Similarly, by monitoring the luminance attenuation of the green light-emitting elements in the non-display area NA, the luminance attenuation of the green light-emitting elements in the display area AA can be inferred, and by monitoring the luminance attenuation of the blue light-emitting elements in the non-display area NA, the luminance attenuation of the blue light-emitting elements in the display area AA can be inferred.

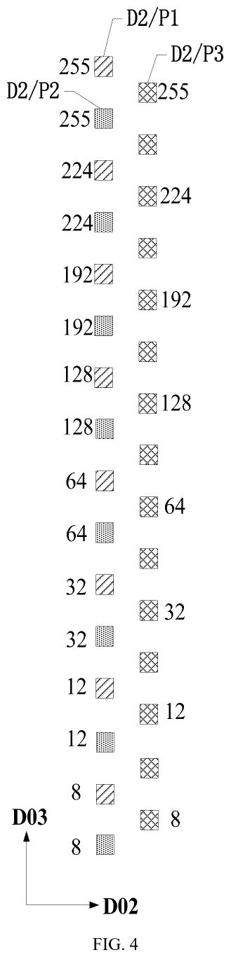

FIG. 4 is a schematic diagram showing a correspondence between part of second light-emitting elements D2 in a non-display area NA and display grayscale. Referring to FIG. 4, in an embodiment of the present disclosure, in the same display frame, at least two second light-emitting elements D2 with the same light-emitting color in the non-display area NA have different display grayscales. In the drawings of the present disclosure, the same graphic filling is used to illustrate light-emitting elements of the same light-emitting color. In an embodiment as shown in FIG. 4, the grayscale of each second light-emitting element is illustrated.

Considering that even the light-emitting elements with the same color may have different driving current, voltage, and other conditions when operating at different grayscales, and also have different luminance attenuation. Therefore, in an embodiment, by setting different display grayscales for at least two second light-emitting elements D2 with the same light-emitting color, these two (or more) second light-emitting elements D2 can operate at different luminance levels. Since the lifespan decay rate of the light-emitting element may be related to the luminance, monitoring the attenuation at different luminance levels can provide a more comprehensive understanding of the overall lifespan characteristics of the light-emitting element of a specific color. Monitoring at a single grayscale may only reflect the attenuation behavior at a specific luminance. By comparing the attenuation rates at different grayscales, a more refined lifespan model can be obtained, thereby more accurately predicting the lifespan of the light-emitting elements of the same color in the display area AA under various actual use luminance.

It should be noted that the display grayscale of at least two second light-emitting elements D2 with the same light-emitting color can be selected according to actual conditions. For example, if there are a large number of second light-emitting elements D2 with the same light-emitting color in the non-display area NA, different grayscales can be set for these second light-emitting elements D2, for example, dozens or hundreds of different grayscales can be selected from 0 to 255, so as to obtain the attenuation data of the second light-emitting elements D2 with the same light-emitting color at different luminance levels, thereby reflecting the changes in the lifespan of the first light-emitting element D1 in the first display area AA more realistically. In an embodiment as shown in FIG. 4, only a few grayscales such as 255, 224, 192, 128, 64, 32, 12, and 8 are selected as examples for illustration, which should not be construed as limiting the present disclosure.

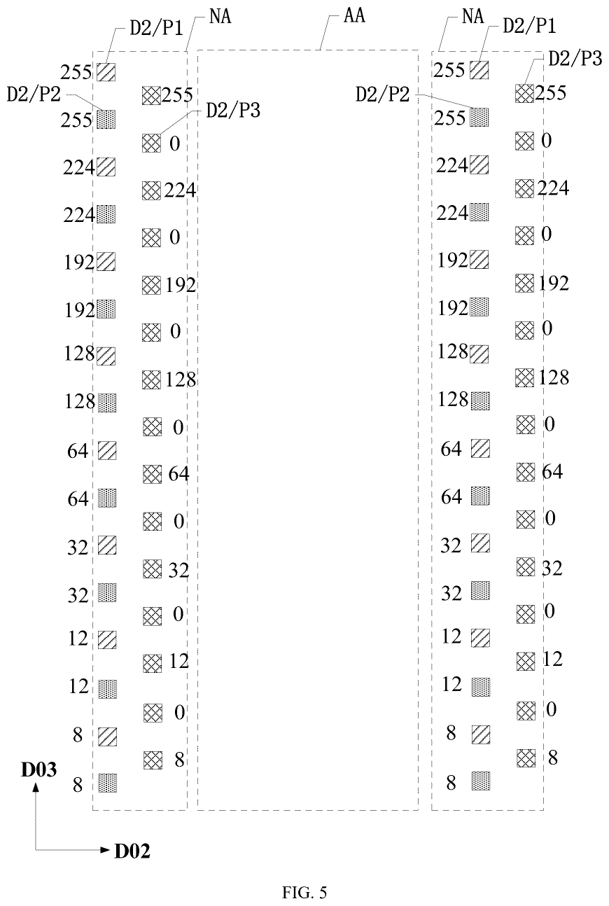

FIG. 5 is a schematic diagram showing a further correspondence between part of second light-emitting elements D2 in a non-display area NA and display grayscale. Referring to FIG. 5, in an embodiment of the present disclosure, in the same display frame, at least two second light-emitting elements D2 with the same light-emitting color in the non-display area NA have the same displayed grayscale. In an embodiment, the same graphic filling is used to illustrate the light-emitting elements of the same light-emitting color.

Considering that for the second light-emitting elements D2 with the same light-emitting color, if only one monitoring point is set for one grayscale, the data of a single monitoring point may be affected by local defects, environmental factors or other uncertainties. Therefore, in n embodiment, by monitoring the luminance attenuation of two (or more) second light-emitting elements D2 with the same grayscale, the data can be compared and averaged to reduce the impact of abnormal fluctuations of a single element or the photosensitive unit 90, or the noise on the overall monitoring result. In addition, multiple monitoring points under the same conditions can provide redundant information. By averaging or comparative analysis, abnormal data can be identified and excluded to obtain a more stable and reliable luminance attenuation trend. When there are at least two second light-emitting elements D2 with the same grayscale and the same light-emitting color in the non-display area NA, if one of the second light-emitting elements D2 or the associated photosensitive unit 90 thereof malfunctions, the other elements with the same grayscale can still continue to provide lifespan monitoring data, ensuring the reliability of the monitoring system and avoiding the failure of the entire monitoring function due to the failure of a single component.

In practical applications, if at least two second light-emitting elements D2 with the same light-emitting color has the same display grayscale, they could be provided at different positions in the non-display area NA of the display panel. That is, the second light-emitting elements D2 with the same grayscale and the same light-emitting color are provided at different positions in the non-display area NA, which can facilitate monitoring the uniformity of the manufacturing process in the non-display area NA, thereby providing a reference basis for process improvement and quality control. In this embodiment, at least two second light-emitting elements D2 with the same light-emitting color and the same display grayscale are respectively provided at two sides of the display area AA, as an example, which should not be construed as limiting the present disclosure. In some embodiments of the present disclosure, different second light-emitting elements D2 with the same light-emitting color and the same display grayscale may also be provided at the same side of the display area.

In an embodiment of the present disclosure, in different display frames, the display grayscale of the same second light-emitting element D2 in the non-display area NA is the same. In the present disclosure, the second light-emitting element D2 in the non-display area NA is designed to obtain lifespan data, so maintaining the same display grayscale in different frames means that the light-emitting element continues to operate at the same operating point (luminance or current density). In different display frames, the same second light-emitting element D2 in the non-display area NA maintains grayscale consistency, which can ensure that the second light-emitting element D2 is always in a preset, stable aging status, avoiding the complexity and uncertainty introduced by frequent changes in the operating point.

In the non-display area NA, due to the fixed operating conditions, the monitoring data of the luminance of the second light-emitting element D2 by the photosensitive unit 90 is purer, mainly reflecting the luminance attenuation of the light-emitting element itself. If the grayscale changes frequently, the luminance data collected each time needs to be normalized in combination with the grayscale information at that time, which increases the complexity of data processing. Fixed grayscale allows the data to be directly used to depict the attenuation curve. After excluding the influence of changes in grayscale, the change curve of the monitored luminance more directly and clearly reflects the intrinsic luminance attenuation trend of the light-emitting element over time.

Referring to FIG. 5, in an embodiment of the present disclosure, in at least one display frame, at least part of the second light-emitting elements D2 in the non-display area NA do not display or have a grayscale of 0. “Not display” can be interpreted as not inputting a drive signal to the corresponding second light-emitting element D2, and the corresponding pixel driving circuit is in a closed state, such as disconnecting certain traces connected to the pixel driving circuit. “Grayscale of 0” can be interpreted as inputting a grayscale signal of 0 to the second light-emitting element D2 to enable the second light-emitting element D2 to reach the lowest luminance level, such that the corresponding pixel driving circuit can be in an active state.

In an embodiment, in the non-display area NA, when some second light-emitting elements D2 do not display or have a grayscale of 0, the corresponding second light-emitting elements D2 do not emit light. By turning off the second light-emitting elements D2 that do not need to emit light or providing them with a grayscale signal of 0, the overall power consumption can be greatly reduced. Especially under prolonged operation of the display, even the tiny power consumption of the non-display area NA may accumulate over time and become significant. For battery-powered mobile devices or application scenarios with strict requirements on energy consumption, power consumption is optimized by turning off the second light-emitting elements D2 that do not need to emit light, which can help extend battery life or reduce operating costs. In addition, the light-emitting elements generate heat when operating. Turning off part of the second light-emitting elements D2 can reduce local heat accumulation in the non-display area NA. Reducing unnecessary heat sources helps maintain lower device temperatures, which has a positive impact on the performance and lifespan of surrounding transistors, the photosensitive unit 90, and the overall panel.

It should be noted that, in an embodiment shown in FIG. 5, only the positions of part of the second light-emitting element D2 with a display grayscale of 0 is illustrated, which should not be construed as limiting the present disclosure. In practical applications, the position of the second light-emitting element D2 that does not emit light can be set according to specific requirements.

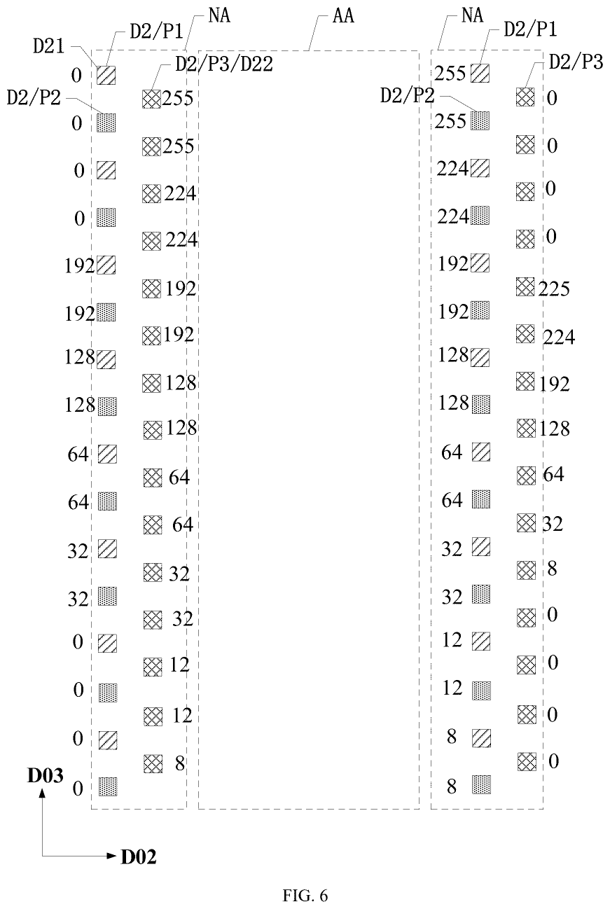

FIG. 6 is a schematic diagram showing a further correspondence between part of second light-emitting elements D2 in a non-display area NA and display grayscale. Referring to FIG. 6, in an embodiment of the present disclosure, the second light-emitting element D2 includes a second A light-emitting element D21 and a second B light-emitting element D22. In at least one display frame, the second A light-emitting element D21 does not display or has a grayscale of 0. That is, the second A light-emitting element D21 does not emit light. The display grayscale of the second B light-emitting element D22 has a grayscale greater than 0. That is, the second B light-emitting element D22 continuously emits light for lifespan monitoring. In the non-display area NA, the second A light-emitting element D21 is provided between the second B light-emitting element D22 and the edge of the display panel.

In an embodiment, by allowing the second light-emitting element D22 to continuously emit light with a grayscale greater than 0 for monitoring, it is ensured that the lifespan data is obtained uninterruptedly. The second light-emitting element D21 is set to not emit light, directly reducing the overall power consumption of the non-display area NA, and cleverly balances the continuous needs of power consumption control and lifespan monitoring.

In the manufacturing process of the display panel, especially the preparation of the thin film transistor array, the closer the area is to the edge of the panel, the worse the process uniformity is, and the more likely it is to have process deviations. For example, the thickness of the deposited semiconductor layer, dielectric layer or metal layer in the edge area may be different from that in the central area. The second A light-emitting element D21, which does not emit light, is arranged at a position closer to the periphery of the non-display area NA, such as a position adjacent to the edge of the display panel, that is, in an area with large process deviation. Since the second A light-emitting element D21 does not emit light for a long time, its potential performance instability (caused by process deviations) does not directly affect the current lifespan monitoring of the second B light-emitting element D22, nor does it affect the normal display function of the display area AA. The second A light-emitting element D21 is arranged in the invalid area at the outermost periphery of the non-display area NA, which full utilizes of these edge spaces that usually do not carry important functions. Such layout avoids occupying valuable space in the display area AA or the more important non-display area NA to arrange the backup elements, thereby maintaining the high pixel density and display quality of the display area AA, and freeing up space for other important driving circuits or photosensitive units.

It should be noted that in an embodiment as shown in FIG. 6, the second A light-emitting elements D21 with a display grayscale of 0 are provided in the four corner areas of the display panel as an example, which should not be construed as limiting the present disclosure.

Referring to FIG. 1, in an embodiment of the present disclosure, the non-display area NA includes at least two pixel groups Z, and at least one of the pixel groups Z include a plurality of second light-emitting elements D2. The second light-emitting elements D2 in at least two pixel groups Z have different light-emitting colors. The display panel is usually composed of the light-emitting elements for the three primary colors of red (R), green (G), and blue (B), and the lifespan decay characteristics of luminescent materials of different colors are often different due to differences in their chemical composition, physical properties, and driving methods. By providing second light-emitting elements D2 of different colors in the pixel groups Z in the non-display area NA, for example, one pixel group Z includes light-emitting elements of red and blue light-emitting colors, and another pixel group Z includes light-emitting elements of green light-emitting color, so that the lifespan monitoring of the light-emitting elements of all main light-emitting colors can be performed to achieve a more accurate and comprehensive overall panel lifespan evaluation. The light-emitting elements in one pixel group are arranged along a second direction D02 or a third direction D03.

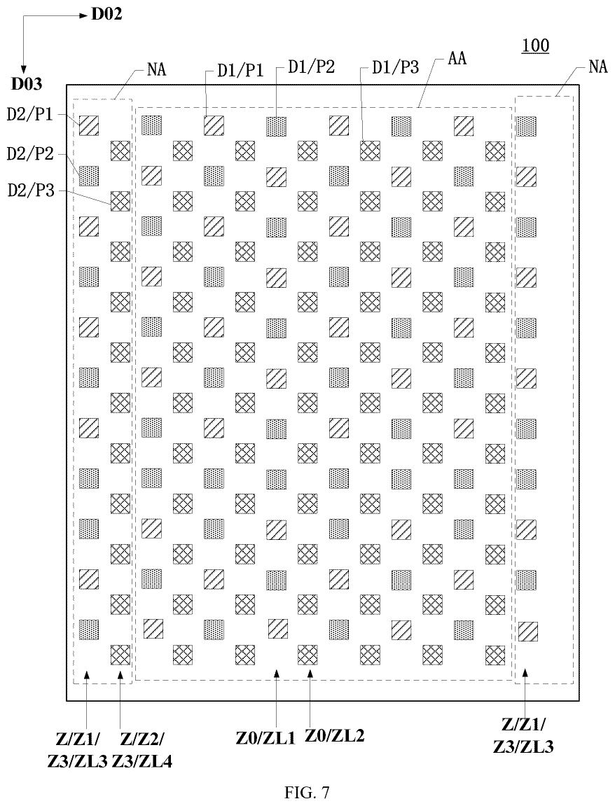

Referring to FIG. 1 and FIG. 7, FIG. 7 is a planar structural diagram of a further display panel according to some embodiments of the present disclosure. In an embodiment of the present disclosure, the pixel group Z includes a first pixel group Z1 and a second pixel group Z2, and the first pixel group Z1 and the second pixel group Z2 include the same number of light-emitting elements. The first pixel group Z1 includes a plurality of first color light-emitting elements P1 and a plurality of second color light-emitting elements P2, and the second pixel group Z2 includes a plurality of third color light-emitting elements P3. In the non-display area NA, the number of the second pixel groups Z2 is less than or equal to the number of the first pixel groups Z1. In an embodiment as shown in FIG. 1, the number of the first pixel groups Z1 is the same as the number of the second pixel groups Z2 in the non-display area NA, and in another embodiment as shown in FIG. 7, the number of the second pixel groups Z2 is less than the number of the first pixel groups Z1 in the non-display area NA.

In some embodiments of the present disclosure, the number of the light-emitting elements included in the first pixel group Z1 is the same as the number of the light-emitting elements included in the second pixel group Z2. The first pixel group Z1 includes the first color light-emitting element P1 and the second color light-emitting element P2, and the second pixel group Z2 only includes the third color light-emitting element P3. Therefore, in one pixel group Z, the total number of the third color light-emitting elements P3 is greater than the total number of the first color light-emitting elements P1, and also greater than the total number of the second color light-emitting elements P2. When the first pixel group Z1 and the second pixel group Z2 are introduced in the non-display area NA, the number of the second pixel group Z2 is less than or equal to the number of the first pixel group Z1, such that the total number of the third color light-emitting elements P3 included in the non-display area NA is greater than or equal to the total number of the first color light-emitting elements P1, and greater than or equal to the total number of the second color light-emitting elements P2. In this way, the same number of first color light-emitting elements P1, second color light-emitting elements P2 and third color light-emitting elements P3 can be selected as light-emitting elements for lifespan monitoring, thereby realizing comprehensive and accurate lifespan monitoring of the light-emitting elements of different colors.

In some embodiments of the present disclosure, one of the first color light-emitting element P1 and the second color light-emitting element P2 is a red light-emitting element, the other is a blue light-emitting element, and the third color light-emitting element P3 is a green light-emitting element.

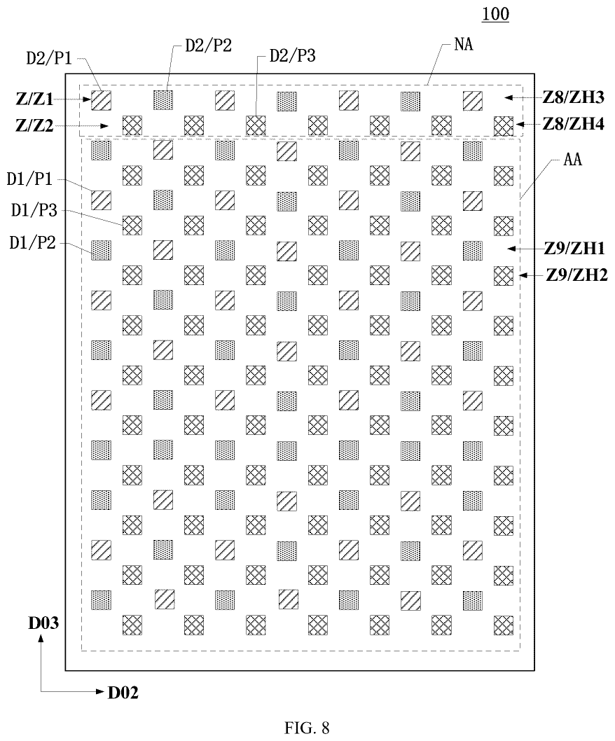

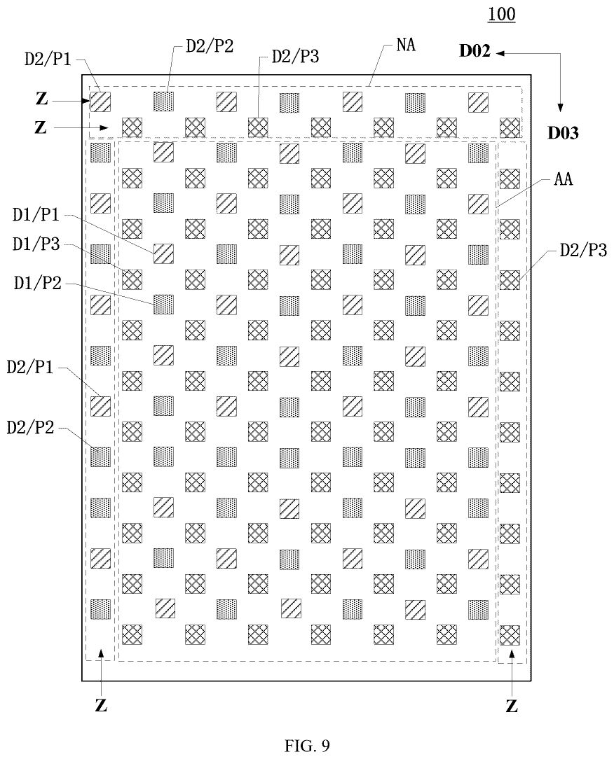

Referring to FIG. 1, FIG. 7, FIG. 8 and FIG. 9, in an embodiment of the present disclosure, in the non-display area NA, at least two pixel groups Z are arranged along the second direction D02, and a plurality of second light-emitting elements D2 in one pixel group Z are arranged along the third direction D03, and the second direction D02 intersects with the third direction D03. Meanwhile/alternatively, in the non-display area NA, at least two pixel groups Z are arranged along the third direction D03, and a plurality of second light-emitting elements D2 in one pixel group Z are arranged along the second direction D02, and the second direction D02 intersects with the third direction D03. FIG. 8 and FIG. 9 are planar structural diagrams of other display panels according to some embodiments of the present disclosure, respectively.

In an embodiment, one of the second direction D02 and the third direction D03 can be embodied as a row direction, and the other can be embodied as a column direction. When the second direction D02 is the row direction, the third direction D03 is the column direction, and the pixel groups Z are arranged along the second direction D02, referring to FIG. 7, which is equivalent to introducing pixel columns (i.e., pixel groups Z) along the row direction on the left side frame and/or the right side frame of the display area AA, and at least part of the second light-emitting elements D2 in these pixel columns are used as light-emitting elements for lifespan monitoring. Considering that the photosensitive unit 90 corresponding to the second light-emitting element D2 is connected to the binding pad of the display panel (for example, provided at the lower frame position, for binding a flexible circuit board or a control chip) through the photosensitive driving circuit, when the second light-emitting element D2 is provided at the left side frame and/or the right side frame of the display panel, it can be convenient for the photosensitive driving circuit to be electrically connected to the binding pad, which is conducive to simplifying the wiring design, and reducing the wiring complexity and signal interference.

In some embodiments of the present disclosure, for example, referring to FIG. 8, when the second direction D02 is the row direction, the third direction D03 is the column direction, and the pixel groups Z are arranged along the third direction D03, which is equivalent to introducing pixel rows (i.e., pixel groups Z) along the column direction on the upper side frame and/or the lower side frame of the display area AA, and at least part of the second light-emitting elements D2 in these pixel rows are used as light-emitting elements for lifespan monitoring. It should be noted that, considering that the binding pad may be provided at the position of the lower frame of the display panel, in order to avoid causing excessive width of the lower frame, the second light-emitting element D2 can be provided only in the upper frame. Without considering the influence of the width of the frame, the second light-emitting element D2 can also be provided in the lower frame to facilitate the connection between the photosensitive driving circuit corresponding to the photosensitive unit and the binding pad.

In some embodiments of the present disclosure, for example, referring to FIG. 9, when the second direction D02 is the row direction, the third direction D03 is the column direction, the pixel columns (i.e., pixel groups Z) can also be introduced in the left side frame and/or right side frame of the display panel, and the pixel rows (i.e., pixel groups Z) can be introduced in the upper side frame and/or lower side frame of the display panel. In an embodiment as shown FIG. 9, the second light-emitting elements D2 are introduced in the left frame, right frame and upper frame of the display panel, respectively, which should not be construed as limiting the present disclosure. In this way, the number of the second light-emitting elements D2 used for lifespan monitoring in the display panel can be increased, thereby achieving lifespan monitoring of the second light-emitting elements D2 with more grayscales and obtaining the lifespan of the first light-emitting elements with more grayscales in the display panel. It should be noted that in some embodiments of the present disclosure, the second light-emitting elements D2 can also be introduced in the left frame and right frame, as well as the upper frame and lower frame of the display area AA.

It should be noted that in an embodiment as shown FIG. 9, only one pixel column in the left frame, one pixel column in the right frame, and two pixel rows in the upper frame of the display panel are introduced, which should not be construed as limiting the present disclosure. In actual applications, the number of pixel columns actually provided in the left frame and the right frame, as well as the number of pixel rows actually introduced in the upper frame and the lower frame can be set according to actual conditions.

Referring to FIG. 1 and FIG. 7, in an embodiment of the present disclosure, the display panel includes a plurality of pixel column groups arranged along the second direction D02, and at least one of the pixel column groups includes a first pixel column group Z0 provided in the display area AA and a second pixel column group Z3 provided in the non-display area NA. The first pixel column group Z0 includes a first pixel column ZL1 and a second pixel column ZL2 arranged alternately along the second direction D02, and the second pixel column group Z3 includes a third pixel column ZL3 and a fourth pixel column ZL4 arranged along the second direction D02. The first pixel column ZL1 and the third pixel column ZL3 include the first color light-emitting element P1 and the second color light-emitting element P2 arranged alternately along the third direction D03, respectively. The second pixel column ZL2 and the fourth pixel column ZL4 include a plurality of third color light-emitting elements P3 arranged along the third direction D03, respectively. The second direction D02 intersects with the third direction D03.

In an embodiment, by providing the second pixel column group Z3 in the non-display area NA that is highly similar or corresponding to the pixel column arrangement in the display area AA, the second light-emitting element D2 in the non-display area NA can accurately map the pixels of different colors and at different positions in the display area AA. Through the third pixel column ZL3 in the non-display area NA (the pixel arrangement is the same as the first pixel column ZL1 in the display area AA), the lifespan decay of the first color light-emitting element P1 and the second color light-emitting element P2 in the display area AA can be monitored. Through the fourth pixel column ZL4 in the non-display area NA (the pixel arrangement is the same as the second pixel column ZL2 in the display area AA), the lifespan decay of the third color light-emitting element P3 in the display area AA can be monitored. Such one-to-one or one-to-many mapping relationship enables the lifespan monitoring data of the non-display area NA to more directly and accurately reflect the actual decay status of the pixels in the display area AA, providing a reliable basis for accurate dynamic compensation and calibration.

In addition, in some embodiments of the present disclosure, the pixel arrangement of the display area AA and the non-display area NA has a highly similar structure (such as the staggered arrangement of columns and the color arrangement within the columns), so the manufacturing process of the pixels in the non-display area NA and the display area AA can be highly reused. Such a design allows for the simultaneous manufacturing of pixel structures with the same light-emitting color in the display area AA and the non-display area NA in the same process steps such as photolithography, deposition, and etching, thereby avoiding the design of a completely different and independent manufacturing process for the non-display area NA, greatly simplifying the manufacturing complexity, reducing production costs, and potentially improving overall yield.

It should be noted that when the second pixel column group Z3 is introduced in the non-display area NA to realize the lifespan monitoring of the light-emitting elements of different light-emitting colors, the number, position and display grayscale of the second light-emitting elements D2 used for lifespan monitoring in the second pixel column group Z3 can be selected according to actual needs. In order to reduce power consumption, the number and position of the second light-emitting elements D2 that do not emit light can be selected in the second pixel column group Z3 according to actual needs, which should not be construed as limiting the present disclosure. For example, at least one second light-emitting element D2 in the area close to the edge of the display panel can be selected as the second light-emitting element D2 that does not emit light to reduce the overall power consumption of the panel.

Referring to FIG. 1, in an embodiment of the present disclosure, in the non-display area NA, the third pixel column ZL3 and the fourth pixel column ZL4 in the same second pixel column group Z3 are provided at the same side of the display area AA along the second direction D02, and the second light-emitting element D2 includes a light-emitting element provided in the second pixel column group Z3.

In an embodiment, describes a specific position and composition of the second pixel column group Z3 in the non-display area NA. The third pixel column ZL3 and the fourth pixel column ZL4 in the same second pixel column group Z3 are provided at the same side of the display area AA along the second direction D02. Since the third pixel column ZL3 includes the first color light-emitting element P1 and the second color light-emitting element P2, and the fourth pixel column ZL4 includes the third color light-emitting element P3, the third pixel column ZL3 and the fourth pixel column ZL4 in the same second pixel column group Z3 are centrally provided at the same side of the display area AA, and the left or right frame space of the display panel can be used to realize the lifespan monitoring of the light-emitting elements of the three light-emitting colors in the display area AA.

In practical applications, the second pixel column group Z3 may be provided only on the left frame of the display panel, or only on the right frame of the display panel, or on the left frame and the right frame of the display panel, respectively, which should not be construed as limiting the present disclosure. During the manufacturing process of the display panel, due to the process deviations (for example, uniformity problems in coating, evaporation, etching, etc.), there may be slight differences in the performance and lifespan decay characteristics of the left and right frames. By setting monitoring points at both the left and right sides, lifespan data of both sides can be obtained simultaneously. Double-side monitoring is conductive to identifying and distinguishing the overall aging trend of the panel and the local non-uniform attenuation, thereby providing more accurate lifespan prediction and more refined compensation strategies. In addition, if the second pixel column group Z3 or its related photosensitive unit 90 at one of the left and right sides malfunctions, the second pixel column group Z3 at the other side can still continue to provide key lifespan monitoring data, thereby enhancing the redundancy and reliability of monitoring.

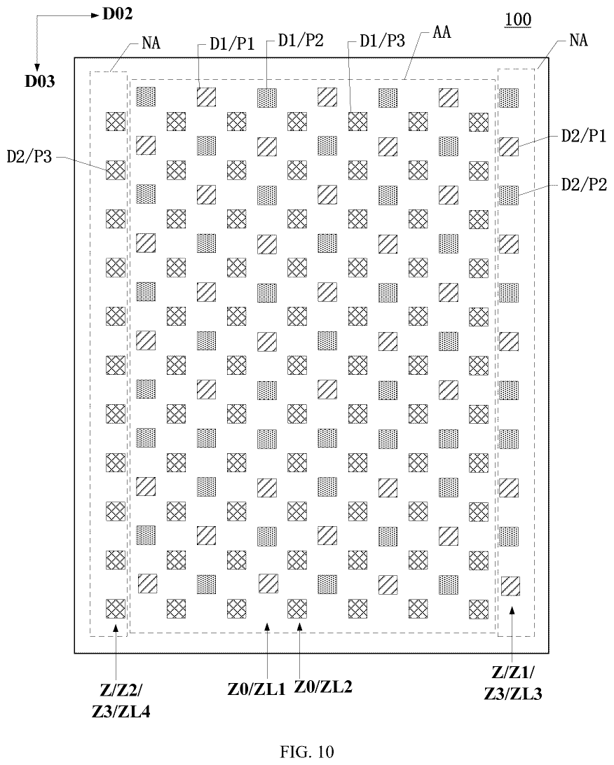

Referring to FIG. 10, FIG. 10 is a planar structural diagram of a further display panel according to some embodiments of the present disclosure. In an embodiment of the present disclosure, along the second direction D02, the third pixel column ZL3 and the fourth pixel column ZL4 in the same second pixel column group Z3 are provided at two sides of the display area AA along the second direction D02, respectively, and the second light-emitting elements D2 include the light-emitting elements provided in the third pixel column ZL3 and the fourth pixel column ZL4. In this way, by introducing one third pixel column ZL3 in one of the left frame and the right frame of the display panel, and introducing one fourth pixel column ZL4 in the other, the lifespan monitoring of the second light-emitting elements D2 with three different light-emitting colors can be realized, thereby realizing the lifespan monitoring of the first light-emitting elements D1 with three different light-emitting colors in the display area AA. In an embodiment, the third pixel column ZL3 and the fourth pixel column ZL4 in the second pixel column group Z3 are arranged at two sides of the display area AA along the second direction D02, respectively, which can realize life monitoring of the light-emitting elements of different light-emitting colors, and can facilitate reducing the number of pixel columns introduced in the left and right frames of the display area AA, thereby realizing a narrow-frame design of the display panel.

The above embodiment illustrates a solution of introducing pixel column groups in the non-display area NA to monitor the lifespan of the second light-emitting element D2. In some embodiments of the present disclosure, a pixel row group may be introduced in the non-display area NA to monitor the lifespan of the second light-emitting element D2. For example, referring to FIG. 8, in an embodiment of the present disclosure, the display panel includes a plurality of pixel row groups arranged along the third direction D03, at least one of the pixel row groups includes a first pixel row group Z9 provided in the display area AA and a second pixel row group Z8 provided in the non-display area NA. The first pixel row group Z9 includes a first pixel row ZH1 and a second pixel row ZH2 arranged alternately along the third direction D03, and the second pixel row group Z8 includes a third pixel row ZH3 and a fourth pixel row ZH4 arranged along the third direction D03. The first pixel row ZH1 and the third pixel row ZH3 include the first color light-emitting element P1 and the second color light-emitting element P2 arranged alternately along the second direction D02, respectively, the second pixel row ZH2 and the fourth pixel row ZH4 include the third color light-emitting elements P3 arranged along the second direction D02, respectively, and the second direction D02 intersects with the third direction D03. The second light-emitting element D2 is provided in the second pixel row group Z8, and the second pixel row group Z8 is provided at at least one side of the display area AA along the third direction D03.

In an embodiment, the second pixel row group Z8 is introduced at the position of the upper frame of the display panel, the third pixel row ZH3 in the second pixel row group Z8 and the third pixel row ZH3 in the first pixel row group Z9 in the display area AA have the same arrangement of the light-emitting elements, and the fourth pixel row ZH4 in the second pixel row group Z8 and the second pixel row ZH2 in the display area AA have the same arrangement of the light-emitting elements.

By providing the second pixel row group Z8 in the non-display area NA that is highly similar or corresponding to the first pixel row group Z9 in the display area AA, the second light-emitting element D2 in the non-display area NA can accurately map the pixels of different colors and at different positions in the display area AA. Through the third pixel row ZH3 in the non-display area NA (the pixel arrangement is the same as the first pixel row ZH1 in the display area AA), the lifespan decay of the first color light-emitting element P1 and the second color light-emitting element P2 in the display area AA can be monitored. Through the fourth pixel row ZH4 in the non-display area NA (the pixel arrangement is the same as the second pixel row ZH2 in the display area AA), the lifespan decay of the third color light-emitting element P3 in the display area AA can be monitored. Such one-to-one or one-to-many mapping relationship enables the lifespan monitoring data of the non-display area NA to more directly and accurately reflect the actual decay status of the pixels in the display area AA, providing a reliable basis for accurate dynamic compensation and calibration.

In addition, in some embodiments of the present disclosure, the pixel arrangement of the display area AA and the non-display area NA has a highly similar structure (such as the staggered arrangement of rows and the color arrangement within the rows), so the manufacturing process of the pixels in the non-display area NA and the display area AA can be highly reused. Such a design allows for the simultaneous manufacturing of pixel structures with the same light-emitting color in the display area AA and the non-display area NA in the same process steps such as photolithography, deposition, and etching, avoiding the design of a completely different and independent manufacturing process for the non-display area NA, greatly simplifying the manufacturing complexity, reducing production costs, and potentially improving overall yield.

It should be noted that when the second pixel row group Z8 is introduced in the non-display area NA to realize the lifespan monitoring of the light-emitting elements of different light-emitting colors, the number, position and display grayscale of the second light-emitting elements D2 used for lifespan monitoring in the second pixel row group Z8 can be selected according to actual needs. In order to reduce power consumption, the number and position of the second light-emitting elements D2 that do not emit light can be selected in the second pixel row group Z8 according to actual needs, which should not be construed as limiting the present disclosure. For example, at least one second light-emitting element D2 in the area close to the edge of the display panel can be selected as the second light-emitting element D2 that does not emit light to reduce the overall power consumption of the panel.

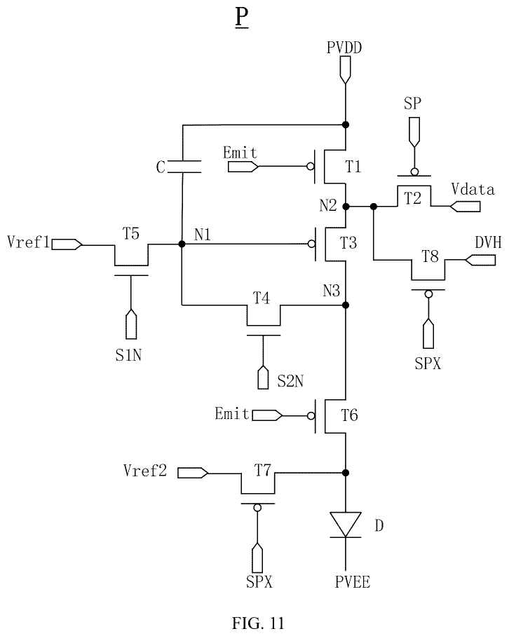

FIG. 11 is a schematic structural diagram of a pixel driving circuit according to some embodiments of the present disclosure. Referring to FIG. 11, in an embodiment of the present disclosure, the display panel further includes a pixel driving circuit P, and the pixel driving circuit P is electrically connected to the light-emitting element D.

Taking FIG. 11 as an example, the pixel circuit includes a transistor T1, a transistor T2, a transistor T3, a transistor T4, a transistor T5, a transistor T6, a transistor T7, a transistor T8 and a capacitor C. It should be noted that, referring to FIG. 2, in the pixel driving circuit connected to the second light-emitting element D2 in the non-display area NA, the first transistor 81 includes the above transistors T1 to T8. The transistor T3 is a driving transistor used to provide a driving current to the light-emitting element D, and a gate, a first electrode and a second electrode of the driving transistor are connected to a first node N1, a third node N3 and a second node N2, respectively. The transistor T5 has a first electrode and a second electrode connected to a gate reset signal end Vref1 and the first node N1, respectively, and a gate connected to a first control signal end S1N for receiving a reset control signal. The transistor T5 is used to provide the gate reset signal Vref1 to the first node N1. The transistor T2 has a first electrode and a second electrode connected to a data voltage signal end Vdata and the second node N2, respectively, and a gate configured to receive a control signal SP. The transistor T2 is configured to transmit the data voltage signal Vdata to the second node N2. It should be noted that the signal end and the signal transmitted by the signal end in the embodiments of the present disclosure are represented by the same reference signs. The transistor T4 has a first electrode and a second electrode connected to the third node N3 and the first node N1, respectively, and a gate connected to a second control signal end S2N for receiving a control signal S2N. The transistor T4 is used to perform threshold compensation on the transistor T3. The transistor T7 has a first electrode and a second electrode connected to an anode reset signal end Vref2 and the first electrode of the light-emitting element D, respectively, and a gate connected to a control signal end SPX. The transistor T7 is used to reset the first electrode (e.g., anode) of the light-emitting element D. The transistor T8 has a first electrode and a second electrode connected to a bias voltage adjustment signal end DVH and the second node N2, respectively, and a gate connected to the control signal end SPX. The transistor T1 has a first electrode and a second electrode connected to a first power signal end PVDD and the second node N2, respectively, and a gate connected to a light-emitting control signal end Emit. The transistor T6 has a first electrode and a second electrode connected to the third node N3 and the first electrode of the light-emitting element D, respectively, and a gate connected to the light control signal end Emit for transmitting the driving current to the light-emitting element D. The second electrode of the light-emitting element D is configured to receive a second power signal PVEE. It should be noted that the gates of the transistor T7 and the transistor T8 are connected to the control signal end SPX in some embodiments of the present disclosure as examples, which should not be construed as limiting the present disclosure.

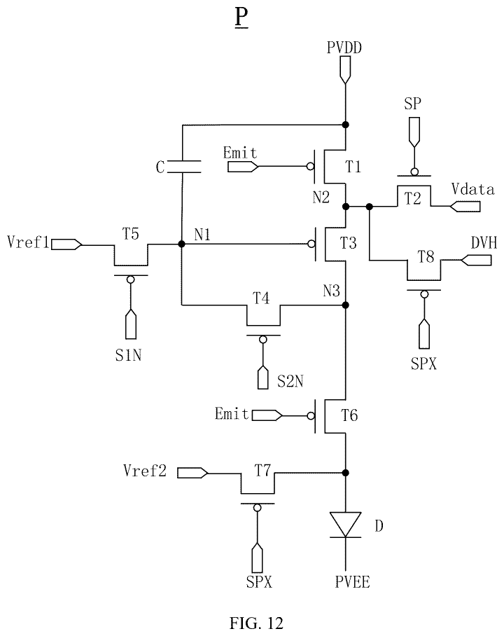

It should also be noted that the pixel circuit in FIG. 11 is just for illustration, and the present disclosure is not limited to the specific structure of the pixel circuit. In an embodiment as shown in FIG. 11, the transistor T4 and the transistor T5 that are connected to the first node N1 are N-type transistors, and the N-type transistors may be oxide transistors. The signal for controlling the conduction of the transistor T4 and the transistor T5 is a high potential signal, and the other transistors are all P-type transistors. In an embodiment, the transistor T4 and the transistor T5 are N-type transistors, and the N-type transistors are oxide transistors, which helps reduce the leakage of the transistor T4 and the transistor T5 to the first node N1, thereby maintaining the stability of the potential of the gate of the driving transistor connected to the first node N1. In some embodiments, the pixel driving circuit can also be embodied in other structures. For example, referring to FIG. 12. FIG. 12 is schematic structural diagram of a further pixel driving circuit according to some embodiments of the present disclosure, with the same connection relationship and operating principle as FIG. 11. The only difference from FIG. 11 is that the transistor T4 and the transistor T5 are P-type transistors, and the P-type transistors are turned on under the control of the low potential signal. When each transistor as shown in FIG. 12 is a P-type transistor, in some embodiments, it is conductive to simplifying the manufacturing process of the pixel circuit.

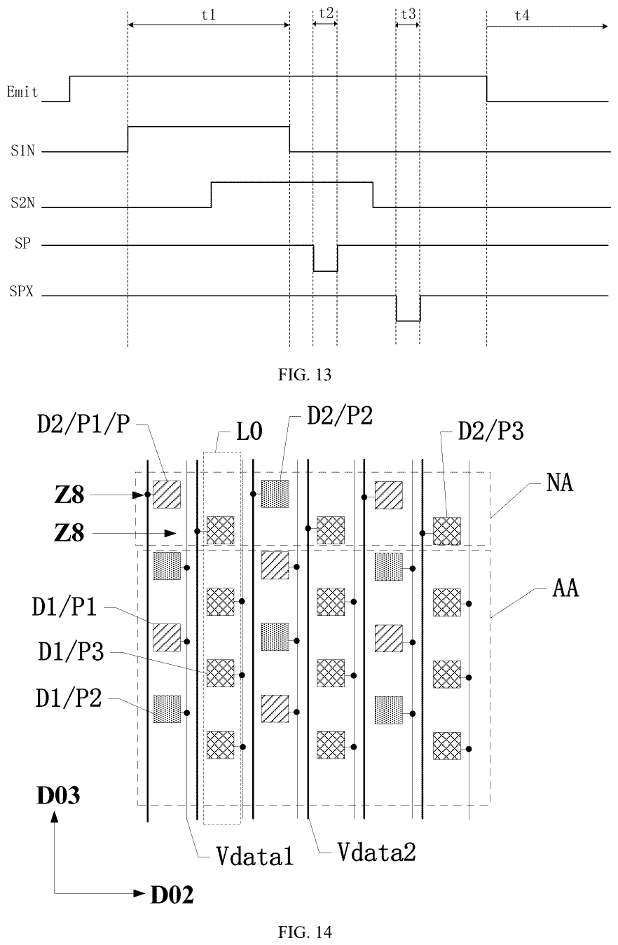

The operating principle of FIG. 11 will be described below in conjunction with FIG. 13. The operating principle of the pixel circuit in FIG. 12 can refer to this embodiment. FIG. 13 is a timing diagram of the pixel driving circuit in FIG. 11. In conjunction with FIG. 11 and FIG. 13, the specific operating process of the pixel driving circuit P includes an initialization phase t1, a data writing and threshold compensation phase t2, a bias voltage phase t3, and a light-emitting phase t4.

In the initialization phase t1, the high potential signal of the first control signal S1N controls the transistor T5 to turn on, and the gate reset signal Vref1 is transmitted to the control terminal of the transistor T3 for initialization, so as to eliminate the residual charge of the previous frame to improve the display effect of the display panel. In the present disclosure, during the partial time period of the initialization phase t1, there is a time of coincidence between the effective levels of the first control signal S1N and the second control signal S2N, which is conducive to improving the hysteresis problem of the driving transistor during the initialization phase.

In the data writing and threshold compensation phase t2, the transistor T5 is turned off, the control signal SP controls the transistor T2 to be turned on, the second control signal S2N controls the transistor T4 to be turned on, and the data voltage signal Vdata is written into the transistor T3 through the transistor T2. The transistor T4 is connected between the gate and the first electrode of transistor T3, and the threshold voltage of transistor T3 can be captured to the gate of transistor T3 to achieve compensation of the threshold voltage and self-compensate for the deviation of the threshold voltage of the driving transistor.

In the bias phase t3, the control signal SPX controls the transistor T8 to be turned on, and the bias voltage adjustment signal DVH is transmitted to the second electrode (i.e., the second node N2) of the driving transistor through the transistor T8 to adjust the bias state of the driving transistor. The control signal SPX controls the transistor T7 to be turned on, and the anode reset signal Vref2 is transmitted to the anode of the light-emitting element D through the transistor T7 to reset the light-emitting element D.

In the light-emitting phase t4, the transistor T2, the transistor T4, the transistor T5 and the transistor T7 are all turned off, the transistor T1, the transistor T3 and the transistor T6 are all turned on, the driving current is transmitted to the first electrode of the light-emitting element D, and the light-emitting element D emits light. It should be noted that the timing diagram of FIG. 13 is only for illustration and should not be interpreted as limiting the present disclosure. In some further embodiments of the present disclosure, pixel circuits with different structures may correspond to different timings.

It should be noted that the first light-emitting element D1 and the second light-emitting element D2 in an embodiment of the present disclosure can be driven by the pixel driving circuit according to the above embodiments, which should not be construed as limiting the present disclosure.

FIG. 14 is a schematic diagram showing a connection between a pixel driving circuit and a data line of a display panel according to some embodiments of the present disclosure. The display panel includes a plurality of pixel columns L0 arranged along the second direction D02, and at least one second light-emitting element D2 in the non-display area NA and a column of first light-emitting elements D1 in the display area AA are provided in the same pixel column L0. In the same pixel column L0, pixel driving circuits P corresponding to the first light-emitting elements D1 are connected to the same data line Vdata1, and a pixel driving circuit P corresponding to the second light-emitting element D2 is connected to another data line Vdata2. It should be noted that, in order to facilitate reflecting the connection relationship between the pixel driving circuit and the data line, in an embodiment as shown in FIG. 14, the pixel driving circuit and the corresponding light-emitting element are represented by the same graphic, should not be construed as limiting the present disclosure. In some embodiments of the present disclosure, the arrangement of the pixel driving circuits and the arrangement of the light-emitting elements may be set to be different from each other, for example, the pixel driving circuits may be arranged in an array, and the light-emitting elements may be arranged in the structure shown in FIG. 14.

When the second pixel row group Z8 is introduced in the non-display area NA to realize the lifespan monitoring of light-emitting elements of different light-emitting colors, the second light-emitting element D2 in the non-display area NA and the first light-emitting element D1 in the display area AA are integrated into the same pixel column L0, that is, they can share the same pixel driving circuit layout and even most of steps in the manufacturing process (such as TFT manufacturing and light-emitting layer deposition). The only difference may be the connection method of the data line. Such a design minimizes the additional manufacturing complexity of the monitoring function of the non-display area NA. The mature technology and production line of the display area AA can be directly reused, without the requirement of designing and manufacturing a completely independent set of driving circuits and pixel structures for the monitoring function,, which significantly reduces manufacturing costs, improves production efficiency, and may improve the yield rate of the overall panel. Since the display area AA and non-display area NA elements are produced under the same and verified process conditions, the consistency of their performance and reliability is higher.

In an embodiment, a plurality of first light-emitting elements D1 in the same pixel column L0 are connected to one data line, and the second light-emitting element D2 is connected to another data line, so that an independent but controlled driving current/grayscale can be applied to the second light-emitting element D2. Such configuration ensures that the driving conditions of the second light-emitting element D2 (except the data signal itself) are highly consistent with the first light-emitting element D1 in the display area AA, such that its lifespan decay mode can more accurately simulate the actual decay of the light-emitting element in the display area AA. Through the independent data line, a specific grayscale can be set for the second light-emitting element D2, and the second light-emitting elements D2 in different pixel columns L0 can receive different grayscale signals to obtain lifespan data of multiple points without affecting the normal image of the display area AA.

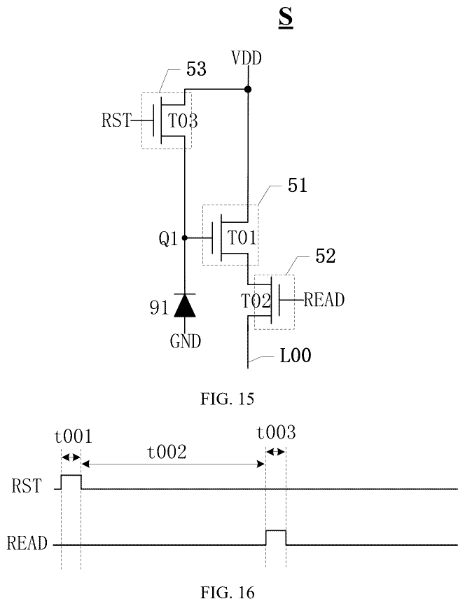

FIG. 15 is a schematic circuit diagram of a photosensitive driving circuit according to some embodiments of the present disclosure. Referring to FIG. 2 and FIG. 15, in an embodiment of the present disclosure, the photosensitive unit 90 further includes a photosensitive driving circuit S electrically connected to the photosensitive element 91, and the transistor included in the photosensitive driving circuit S is the second transistor 82. The photosensitive element 91 is electrically connected to a first sensing node Q1 and a common voltage structure GND, respectively, and the common voltage structure GND is used to provide a common voltage signal. The photosensitive driving circuit S includes a control module 51 and an output module 52 connected to the control module 51. The control module 51 is configured to output a first signal to the output module 52 in response to at least a signal of the first sensing node Q1 and a sensing driving signal VDD. The output module 52 is configured to output a sensing signal in response to an output control signal READ and the first signal.

In conjunction with FIG. 2 and FIG. 15, the photosensitive element 91 is the core of the photoelectric conversion, which may be a photodiode, a photoresistor or a phototransistor. When receiving the light emitted by the second light-emitting element D2, the resistance, current or voltage of the photosensitive element 91 changes. One end of the photosensitive element 91 is connected to the first sensing node Q1, which carries the original, unprocessed analog signal after the photosensitive element 91 converts the light signal into an electrical signal. The other end of the photosensitive element 91 is connected to the common voltage structure GND, and the common voltage structure GND is used to provide the common voltage signal, which provides the necessary potential reference for the normal operation of the photosensitive element 91, ensuring the stability and accuracy of the signal. In some embodiments of the present disclosure, the common voltage structure GND is a ground terminal. The control module 51 is used to amplify the weak signal on the first sensing node Q1. For example, if the first sensing node Q1 receives a photocurrent, the control module 51 converts it into a voltage signal or a current signal and amplifies it to form a first signal. The on-resistance or current of the control module 51 varies in response to changes in the first sensing signal, thereby controlling the magnitude of the current flowing through it. The output module 52 is turned on under the control of the output control signal READ and outputs the first signal. In this way, through the cooperation of the control module 51 and the output module 52, the change in light intensity sensed by the photosensitive element 91 is reliably converted into a quantifiable voltage or current change.

In some embodiments of the present disclosure, the control module 51 is embodied as an amplifying transistor T01 (which may further be embodied as a source follower amplifier), and the output module 52 is embodied as a switching transistor T02. The amplifying transistor T01 generates a source-drain current proportional to the amount of charge input the gate of the first sensing node Q1 of the amplifying transistor T01.

In some embodiments of the present disclosure, the photosensitive driving circuit S further includes a reset module 53. A control terminal of the reset module 53 is connected to a reset control terminal RST, a first electrode of the reset module 53 is connected to a reset voltage end VDD (this embodiment is described by taking the example in which the amplifying transistor T01 and the reset module 53 are connected to the same signal end VDD, which should not be construed as limiting the present disclosure), and a second electrode is connected to the first sensing node Q1. The reset module 53 can reset the potential of the first sensing node to the reset voltage of the reset voltage end in response to a control signal of the reset control terminal.

In some embodiments of the present disclosure, the reset module 53 includes a reset transistor T03. The reset transistor T03, the amplifying transistor T01, and the switching transistor T02 may be transistors of the same type, for example, all N-type transistors or P-type transistors, or may be transistors of different types, for example, some of the reset transistor T03, the amplifying transistor T01, and the switching transistor T02 may be P-type transistors, and the rest may be N-type transistors.

Referring to FIG. 2, in the photosensitive driving circuit connected to the photosensitive element 91, the second transistor 82 includes the amplifying transistor T01, the switching transistor T02 and the reset transistor T03 described above.

It should be noted that the structure of the photosensitive driving circuit in the present disclosure is not limited to the structure of the circuit shown in FIG. 15. The photosensitive driving circuit shown in FIG. 15 is just for illustration. In some further embodiments of the present disclosure, various changes may be made to the structure of the photosensitive driving circuit.

The operating process of the photosensitive driving circuit will be described below in conjunction with FIG. 16, taking as an example a case in which the reset transistor T03, the amplifying transistor T01 and the switching transistor T02 are all N-type transistors. FIG. 16 is a timing diagram of a photosensitive driving circuit according to some embodiments of the present disclosure. The photosensitive driving circuit S includes a reset phase, an exposure phase and a readout phase.

In the reset phase t001, the reset transistor T03 is turned on, the switching transistor T02 is turned off, and the first photosensitive node Q1 is quickly charged to VDD (or close to VDD) through the reset transistor T03. At this time, the voltage on the first photosensitive node Q1 reaches the maximum value. The control terminal of the amplifying transistor T01 (connected to the first photosensitive node Q1) is pulled up to VDD, and the amplifying transistor T01 is turned off.

In the exposure phase t002, the reset transistor T03 is turned off, and the switching transistor T02 is also turned off. The first photosensitive node Q1 is disconnected from the signal end VDD. When light is incident on the photosensitive element 91, the photosensitive element 91 generates a photocurrent. This photocurrent continuously discharges the parasitic capacitor connected to the first photosensitive node Q1. As the discharge progresses, the voltage on the first photosensitive node Q1 gradually decreases. The magnitude of the voltage drop is proportional to the light intensity and the exposure time. The stronger the light and the longer the time, the greater the voltage drop. The control terminal voltage of the amplifying transistor T01 decreases with the first photosensitive node Q1, and its output voltage also decreases accordingly. However, at this time, the switching transistor T02 is still turned off and the signal is not yet transmitted.

In the readout phase t003, the reset transistor T03 is turned off, the switching transistor T02 is turned on, and the output voltage of the amplifying transistor T01 (which has reflected the voltage of the photosensitive node after exposure at this time) is transmitted to an output line L00 through the switching transistor T02. The signal on the output line L00 can reflect the lifespan of the light-emitting element, thereby realizing the lifespan monitoring of the light-emitting element.

FIG. 17 is a schematic diagram showing a connection between a photosensitive driving circuit and a photosensitive chip. In an embodiment, the photosensitive driving circuit S is illustrated only in a block diagram, and the specific structure of the photosensitive driving circuit S can be referred to FIG. 15. Referring to FIG. 15 and FIG. 17, in an embodiment of the present disclosure, the control terminal of the output module 52 is electrically connected to a photosensitive chip 09 through a control signal line READ0, and the control signal line READ0 is configured to receive a control signal transmitted by the photosensitive chip 09.

In an embodiment, the control terminal of the output module 52 is electrically connected to the photosensitive chip 09, and the control signal is obtained through the photosensitive chip 09. The photosensitive chip 09 can serve as the central controller of the entire photosensitive unit 90 to uniformly manage the driving, signal acquisition, processing of the photosensitive element 91 and the control of the output module 52. The control terminal of the output module 52 is connected to the photosensitive chip 09 and is directly controlled by the photosensitive chip 09, and the exposure time can be flexibly set. For example, when the light signal emitted by the second light-emitting element D2 is strong, the light energy received by the photosensitive element 91 is large. If the exposure time is too long, the photosensitive element 91 may be saturated, causing the signal to exceed the measurement range and unable to accurately reflect the actual light intensity, or even be damaged. By reducing the exposure time through the photosensitive chip 09, the amount of light integration of the photosensitive element 91 under strong light can be reduced to avoid signal saturation, which ensures that the photosensitive element 91 always operates in its linear response area, so that the output sensing signal can accurately reflect the high-intensity light signal, and the linearity and accuracy of the measurement are maintained. When the light signal emitted by the second light-emitting element D2 is weak, the light energy received by the photosensitive element 91 is small. If the exposure time is too short and the amount of light integration is insufficient, the signal may be overwhelmed by noise, resulting in inaccurate measurement results or failure to monitor effective signals. By extending the exposure time, the amount of light integration of the photosensitive element 91 under weak light can be increased, and more photon energy can be accumulated, which effectively improves the signal-to-noise ratio of weak signals, so that even weak light signals can be clearly monitored and quantified, thereby achieving precise capture of slight luminance attenuation of the display.

For the method shown in FIG. 8, when the second pixel row group Z8 is introduced in the non-display area NA, the number of rows actually introduced in the non-display area NA is small. In the photosensitive element 91 corresponding to the second pixel row group Z8, the control module 51 in the photosensitive driving circuit S can be electrically connected to the photosensitive chip 09 through the control signal line. That is, the control module 51 in the photosensitive driving circuit S is electrically connected to the photosensitive chip 09 in the method shown in FIG. 17.

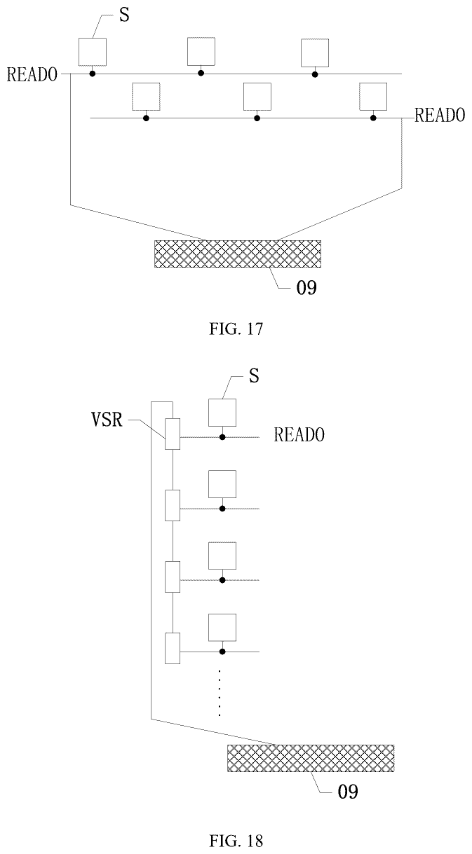

For the method shown in FIG. 1, when the second pixel column group Z3 is introduced in the non-display area NA, it is assumed that the second pixel column group Z3 includes 2 columns and 11 rows of second light-emitting elements D2 as light-emitting elements for lifespan monitoring, and each of them is provided with the photosensitive element 91 and the photosensitive driving circuit S accordingly. The corresponding number of rows is relatively large, and if all of them are directly driven by the photosensitive chip 09, the cost of the photosensitive chip 09 will be greatly increased. Therefore, in an embodiment of the present disclosure, referring to FIG. 18 and FIG. 15, the control terminal of the output module 52 is electrically connected to a shift register circuit VSR through the control signal line READ0, and the control signal line READ0 is configured to receive the control signal transmitted by the shift register circuit VSR. FIG. 18 is a schematic diagram showing a connection between a photosensitive driving circuit and a shift register circuit.

The shift register circuit has the ability of serial input and parallel output. The photosensitive chip 09 only needs to provide a few control lines (usually data input lines, clock lines, etc.) to control up to dozens or even more row drive outputs. Through the shift register circuit, the number of pins of the photosensitive chip 09 can be greatly reduced, thereby reducing the chip cost and the complexity of PCB layout and wiring. Such modular design makes the row drive system of the display panel highly scalable. If more rows of photosensitive driving circuits need to be driven, it is only necessary to increase the number of shift registers without redesigning the main control chip.

In conjunction with FIG. 15 and FIG. 16, in an embodiment of the present disclosure, the photosensitive driving circuit includes the exposure phase t002 and the readout phase t003. In the exposure phase t002, the output module 52 is turned off. In the readout phase t003, the output module 52 is turned on. The duration of a single exposure phase t002 is t11, and the duration of a single readout phase t003 is t12, where t11>N*t12, N≥1.

In the exposure phase t002, the photosensitive element 91 (such as a photodiode or a photosensitive transistor) continuously receives the light signal emitted by the second light-emitting element D2, converts it into the electrical signal, and accumulates it inside the control module 51. This process is called light integration. Since the output module 52 is in the cut-off state, when the photosensitive element 91 accumulates charges, the signal inside the photosensitive element 91 is not disturbed by the external readout circuit, which ensures the purity and accuracy of the light integration process and avoids the contamination of the exposure signal by noise or crosstalk that may be introduced during the readout process. The longer exposure time t11 allows the photosensitive element 91 to accumulate more light signals, and the long integration time can separate the weak light signal from the random noise, thereby significantly improving the signal-to-noise ratio and ensuring that reliable measurement data can be obtained even in the case of severe luminance attenuation.

In the readout phase t003, the charge accumulated by the photosensitive element 91 is quickly converted into a voltage or current signal and transmitted through the output module 52 that is turned on. This signal is the final sensing signal, which represents the light intensity information accumulated in the time period t11 corresponding to the exposure phase t002. The readout phase t002 is designed to be as short as possible to achieve efficient data collection. Fast readout can reduce the entire measurement period and improve the response speed of the system. The short readout time ensures that the photosensitive element 91 does not accumulate additional light during the readout process, thereby avoiding signal oversaturation that may be caused by the readout process.

In some embodiments of the present disclosure, it is set that t11>N*t12, where N may be selected, for example, as the number of rows corresponding to the second light-emitting elements D2 used for lifespan monitoring in the display panel, so that most of the time is used for effective light integration. The photosensitive element 91 has sufficient time to accumulate photons to ensure a sufficiently strong signal during readout. During the exposure phase, the output module 52 is cut off, which means that the subsequent readout circuits connected to the output module 52 can be in a low-power or idle state. These readout circuits only need to be activated and operate during a short readout phase. Such a design can reduce the average power consumption of the entire photosensitive driving circuit and even the subsequent data processing link, because the high-power readout operation only occupies a small part of the entire measurement period.

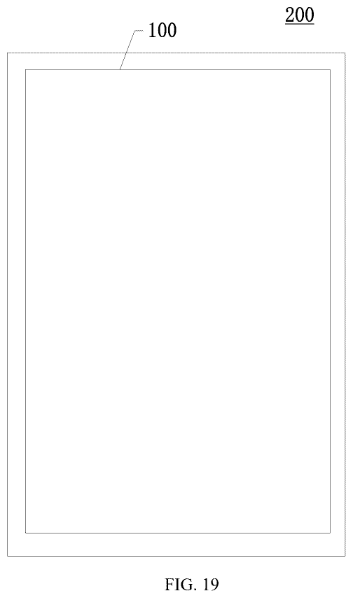

Based on the same inventive concept, the present disclosure also provides a display apparatus. FIG. 19 is a schematic structural diagram of a display apparatus 200 according to some embodiments of the present disclosure. Referring to FIG. 19, the display apparatus 200 includes the display panel 100 according to any one of the above embodiments. The display apparatus 200 according to some embodiments of the present disclosure may be any electronic device with a display function, such as a touch screen, a mobile phone, a tablet computer, a laptop computer, an e-book, or a television. The display apparatus 200 according to some embodiments of the present disclosure has the advantages of the display panel according to some embodiments of the present disclosure. Detailed descriptions of the display panel can be found in the above embodiments, which will not be elaborated in the present disclosure.

It can be understood that FIG. 19 only illustrates one shape of the display apparatus 200 by taking a rectangular structure as an example. In some embodiments of the present disclosure, the display apparatus 200 may also be circular, elliptical or any other feasible shape, should not be construed as limiting the present disclosure.

In summary, the technical solutions according to the embodiments of the present disclosure have the following advantages.

The display panel according to the embodiments of the present disclosure includes the first light-emitting element provided in the display area and the second light-emitting element provided in the non-display area, and the photosensitive unit is further integrated in the non-display area. The photosensitive unit can sense the light emitted by the second light-emitting element and convert the light signal into an electrical signal, which is equivalent to realizing the light emission monitoring of the second light-emitting element, that is, the lifespan monitoring of the second light-emitting element is realized. Due to the fact the second light-emitting element and the first light-emitting element are provided in the same display panel, and have similar lifespan decay characteristics, the lifespan status of the first light-emitting element in the display area can be inferred by monitoring the changes in the light signal of the second light-emitting element in the non-display area. According to the lifespan status of the first light-emitting element, luminance compensation can be selectively performed on the first light-emitting element in the display area (for example, dynamically adjusting the driving voltage or current), which can realize more refined luminance control and color management, effectively improve the visual effect of the display panel, and weaken or avoid the color cast problem caused by luminance attenuation, and is conductive to extending the overall service lifespan of the display panel.

In addition, in the present disclosure, the second light-emitting element and the photosensitive unit are introduced in the non-display area of the display panel, so that the lifespan of the light-emitting element can be monitored in real time during the operation of the display panel without disassembly or destructive testing, thereby reducing the difficulty of monitoring. Compared with relying on laboratory test data, this integrated monitoring solution can better reflect the changes in the lifespan of the light-emitting element in actual usage environments and obtain more accurate monitoring data. Meanwhile, in some embodiments of the present disclosure, the second light-emitting element and the corresponding photosensitive unit are provided in the non-display area of the display panel, which is conductive to affecting the first light-emitting element and related circuit structures in the display area.

It should be noted that, in this context, relational terms such as “first” and “second” are merely used to distinguish one entity or operation from another entity or operation, and do not necessarily require or imply any actual relationship or sequence between these entities or operations. In addition, terms such as “include”, “comprise” or any other variations thereof are intended to cover a non-exclusive inclusion, thus a process, method, item or device including a series of elements includes not only those elements, but also other elements not explicitly listed, or elements inherent in such the process, method, item or device. Without further limitations, an element defined by the statement “including one” does not preclude the presence of another identical element in a process, a method, an article, or a device that includes the element.

The above description is merely specific embodiments of the present disclosure for those skilled in the art to understand or implement the present disclosure. Various modifications to these embodiments will be apparent to those skilled in the art, and the general principles defined herein may be implemented in other embodiments without departing from the spirit or scope of the present disclosure. Accordingly, the present disclosure will not be limited to the embodiments described herein, but should be interpreted to have the broadest scope in conformity with the principles and innovations disclosed in the present disclosure.

What is claimed is:

1. A display panel, comprising:
a substrate;
an array layer and a light-emitting element that are provided at a same side of the substrate; and
a photosensitive unit;
wherein the light-emitting element is located at a side of the array layer away from the substrate, the light-emitting element comprises a first light-emitting element and a second light-emitting element, the first light-emitting element is located in a display area of the display panel, and the second light-emitting element is located in a non-display area of the display panel; and
wherein the photosensitive unit comprises a photosensitive element provided in the non-display area, and the photosensitive element is configured to sense light emitted by the second light-emitting element.

2. The display panel according to claim 1, wherein the photosensitive element overlaps with the second light-emitting element along a first direction, and the first direction is perpendicular to a plane of the substrate.

3. The display panel according to claim 1, further comprising a color filter layer provided at a side of the light-emitting element away from the substrate;
wherein the color filter layer comprises a light-transmitting portion and a light-shielding portion; wherein along a first direction, the light-transmitting portion overlaps with the first light-emitting element and does not overlap with the second light-emitting element, and the light-shielding portion overlaps with the second light-emitting element; and wherein the first direction is perpendicular to a plane of the substrate.

4. The display panel according to claim 1, wherein the light-emitting element comprises a first electrode, a luminescent material layer and a second electrode, and along a first direction, the luminescent material layer is provided between the first electrode and the second electrode, and the first electrode is provided at a side of the luminescent material layer facing the array layer; and wherein the first direction is perpendicular to a plane of the substrate; and
wherein the first electrode of the second light-emitting element is a transparent conductive layer, and the photosensitive element is provided at a side of the second light-emitting element facing the substrate.

5. The display panel according to claim 4, wherein the photosensitive unit is provided in the array layer.

6. The display panel according to claim 4, wherein along the first direction, the photosensitive element overlaps with the second light-emitting element; the photosensitive element comprises a first electrode and a second electrode that are arranged opposite to each other along the first direction, and a photosensitive layer provided between the first electrode and the second electrode; and the second electrode is provided between the photosensitive layer and the substrate, and the second electrode is a light-shielding conductive layer;
wherein the second light-emitting element is electrically connected to at least one first transistor of the array layer, and along the first direction, the first transistor is provided at a side of the second electrode facing the substrate, and the second electrode overlaps with the first transistor; and
wherein along the first direction, the second electrode covers at least part of an active layer of the first transistor.

7. The display panel according to claim 1, wherein the photosensitive unit further comprises at least one second transistor electrically connected to the photosensitive element; and
wherein the array layer comprises a transistor layer, and the transistor layer comprises a plurality of transistors; the at least one second transistor is provided in the transistor layer, and along a first direction, the photosensitive element is provided between the transistor layer and the second light-emitting element, and the first direction is perpendicular to a plane of the substrate.

8. The display panel according to claim 1, wherein each of the first light-emitting element and the second light-emitting element comprises a first color light-emitting element, a second color light-emitting element and a third color light-emitting element, and luminescent material layers of the light-emitting elements of a same light-emitting color provided in the display area and in the non-display area are arranged in a same layer.

9. The display panel according to claim 1, wherein in a same display frame, at least two second light-emitting elements of a same light-emitting color in the non-display area have different display grayscales.

10. The display panel according to claim 1, wherein in a same display frame, at least two second light-emitting elements of a same light-emitting color in the non-display area have a same display grayscale.

11. The display panel according to claim 1, wherein in different display frames, same second light-emitting elements in the non-display area have a same display grayscale.

12. The display panel according to claim 1, wherein in at least one display frame, at least part of the second light-emitting elements in the non-display area do not display or have a grayscale of 0.

13. The display panel according to claim 1, wherein the second light-emitting element comprises a second A light-emitting element and a second B light-emitting element; in at least one display frame, the second A light-emitting element does not display or has a grayscale of 0, and the second B light-emitting element has a grayscale greater than 0; and in the non-display area, the second A light-emitting element is provided between the second B light-emitting element and an edge of the display panel.

14. The display panel according to claim 1, wherein the non-display area comprises at least two pixel groups, one pixel group of the at least two pixel groups comprises a plurality of second light-emitting elements, and the second light-emitting elements in the at least two pixel groups have different light-emitting colors.

15. The display panel according to claim 1, further comprising a plurality of pixel column groups arranged along a second direction;
wherein the plurality pixel column groups comprise a first pixel column group located in the display area and a second pixel column group located in the non-display area; and
wherein the first pixel column group comprises first pixel columns and second pixel columns arranged alternately along the second direction, and the second pixel column group comprises third pixel columns and fourth pixel columns arranged along the second direction;
wherein the first pixel columns and the third pixel columns respectively comprise first color light-emitting elements and second color light-emitting elements arranged alternately along a third direction, and the second pixel columns and the fourth pixel columns respectively comprise a plurality of third color light-emitting elements arranged along the third direction; and the second direction intersects with the third direction.

16. The display panel according to claim 1, further comprising a plurality of pixel row groups arranged along a third direction,
wherein the plurality pixel row groups comprise a first pixel row group located in the display area and a second pixel row group located in the non-display area; the first pixel row group comprises first pixel rows and second pixel rows arranged alternately along the third direction, the second pixel row group comprises third pixel rows and fourth pixel rows arranged along the third direction; and the first pixel rows and the third pixel rows respectively comprise first color light-emitting elements and second color light-emitting elements arranged alternately along a second direction, the second pixel rows and the fourth pixel rows respectively comprise third color light-emitting elements arranged along the second direction, and the second direction intersects with the third direction; and
wherein the second light-emitting element is provided in the second pixel row group, and the second pixel row group is located at at least one side of the display area along the third direction.

17. The display panel according to claim 1, wherein the photosensitive unit further comprises a photosensitive driving circuit electrically connected to the photosensitive element, the photosensitive element is electrically connected to a first sensing node and a common voltage structure, respectively, and the common voltage structure is configured to provide a common voltage signal; the photosensitive driving circuit comprises a control module and an output module connected to the control module, the control module is configured to output a first signal to the output module at least in response to a signal from the first sensing node and a sensing driving signal; and the output module is configured to output a sensing signal in response to an output control signal and the first signal.

18. The display panel according to claim 17, wherein a control terminal of the output module is electrically connected to a photosensitive chip through a control signal line, and the control signal line is configured to receive a control signal transmitted by the photosensitive chip; or
wherein a control terminal of the output module is electrically connected to a shift register circuit through a control signal line, and the control signal line is configured to receive a control signal transmitted by the shift register circuit.

19. The display panel according to claim 17, wherein the photosensitive driving circuit comprises an exposure phase and a readout phase; during the exposure phase, the output module is turned off; during the readout phase, the output module is turned on; and a duration of a single exposure phase is t11, and a duration of a single readout phase is t12, wherein t11>N*t12, and N≥1.

20. A display apparatus, comprising a display panel, wherein the display panel comprises:
a substrate;
an array layer and a light-emitting element that are provided at a same side of the substrate; and
a photosensitive unit;
wherein the light-emitting element is located at a side of the array layer away from the substrate, the light-emitting element comprises a first light-emitting element and a second light-emitting element, the first light-emitting element is located in a display area of the display panel, and the second light-emitting element is located in a non-display area of the display panel; and
wherein the photosensitive unit comprises a photosensitive element provided in the non-display area, and the photosensitive element is configured to sense light emitted by the second light-emitting element.
